(19) United States
(12) Patent Application Publication
(10) Pub. No.: US 2019/0198453 A1
(43) Pub. Date: Jun. 27, 2019

(54) SEMICONDUCTOR DEVICE AND METHOD OF MANUFACTURING THE SAME

(71) Applicant: RENESAS ELECTRONICS CORPORATION, Tokyo (JP)

(72) Inventor: Hiroaki SEKIKAWA, Tokyo (JP)

(21) Appl. No.: 16/194,005

(22) Filed: Nov. 16, 2018

(30) Foreign Application Priority Data
Dec. 25, 2017 (JP) 2017-247471

(51) Int. Cl. H01L 23/00; H01L 21/762; H01L 21/78

(52) U.S. Cl. CPC H01L 23/562; H01L 21/78; H01L 21/76224

(57) ABSTRACT

It is prevented that reliability of a semiconductor device is reduced due to advancement of cracking or chipping within a substrate from a scribe region side to a circuit region side of a semiconductor chip. A dummy isolation part is formed from the upper surface to an intermediate depth of the substrate in a peripheral region that is a part of a scribe region adjacent to a seal ring region, and is not cut during dicing. The dummy isolation part having a DTI structure is disposed so as to surround the circuit region and the seal ring region.

### CROSS-REFERENCE TO RELATED APPLICATIONS

The disclosure of Japanese Patent Application No. 2017-247471 filed on Dec. 25, 2017 including the specification, drawings and abstract is incorporated herein by reference in its entirety.

### BACKGROUND

The present invention relates to a semiconductor device and a method of manufacturing the semiconductor device, and specifically relates to a technique effective in use for a semiconductor device having a deep trench isolation (DTI) structure and for a method of manufacturing the semiconductor device.

Some semiconductor device has a DTI structure, which includes an insulating film formed in a trench having an aspect ratio higher than 1 as a ratio of depth to width of the trench, in a main surface of a semiconductor substrate. As well known, a substrate contact plug is formed in such a deep trench formed in the main surface of the semiconductor substrate and coupled to the semiconductor substrate at a bottom surface of the trench.

A seal ring made of a metal component formed in a peripheral portion of a semiconductor chip as a structure to prevent infiltration of water into a circuit region of a semiconductor chip due to a dicing step performed to produce a plurality of semiconductor chips by cutting a semiconductor wafer, and prevent the circuit region from being contaminated with metal due to such a dicing step.

Japanese Unexamined Patent Application Publication Nos. 2011-66067 and 2011-151121 describe that a deep trench is used for element isolation. Japanese Unexamined Patent Application Publication No. 2015-37099 describes that a plug is formed in a deep trench and coupled to a semiconductor substrate. Japanese Unexamined Patent Application Publication No. Hei8(1996)-37289 describes a seal ring structure. Japanese Unexamined Patent Application Publication Nos. 2006-165040 and 2004-235357 each describe formation of a dummy pattern.

### SUMMARY

For formation of the DTI structure in a semiconductor chip, it is desirable to further form a dummy pattern of the DTI structure in a scribe region of a semiconductor wafer to be cut in a dicing step during a manufacturing process of a semiconductor device in the light of improving uniformity of polishing, for example. However, when the dummy pattern of the DTI structure is formed in the region to be cut in the dicing step, a semiconductor device may not normally operate due to chipping or cracking caused by existence of the dummy pattern.

Other objects and novel features will be clarified from the description of this specification and the accompanying drawings.

Among the embodiments disclosed in this application, typical one is briefly summarized as follows.

A semiconductor device of one embodiment has a dummy DTI structure that surrounds a circuit region in plan view, and includes a second trench deeper than a first trench filled with an element isolation region.

According to the one embodiment disclosed in this application, reliability of the semiconductor device can be improved.

According to the one embodiment disclosed in this application, a yield of the semiconductor device can be improved.

### BRIEF DESCRIPTION OF THE DRAWINGS

FIG. 1 is a plan view of a semiconductor device of a first embodiment of the invention.

FIG. 2 is a plan view of the semiconductor device of the first embodiment.

FIG. 3 is a plan view of the semiconductor device of the first embodiment.

FIG. 4 is a sectional view along a line A-A in FIG. 3.

FIG. 5 is a sectional view of the semiconductor device of the first embodiment.

FIG. 6 is a plan view of the semiconductor device of the first embodiment.

FIG. 7 is a sectional view along a line B-B in FIG. 6.

FIG. 8 is a sectional view of the semiconductor device of the first embodiment during a manufacturing process of the semiconductor device.

FIG. 9 is a sectional view of the semiconductor device during the manufacturing process following FIG. 8.

FIG. 10 is a sectional view of the semiconductor device during the manufacturing process following FIG. 9.

FIG. 11 is a sectional view of the semiconductor device during the manufacturing process following FIG. 10.

FIG. 12 is a sectional view of the semiconductor device during the manufacturing process following FIG. 11.

FIG. 13 is a sectional view of the semiconductor device during the manufacturing process following FIG. 12.

FIG. 14 is a sectional view of the semiconductor device during the manufacturing process following FIG. 13.

FIG. 15 is a sectional view of the semiconductor device during the manufacturing process following FIG. 14.

FIG. 16 is a plan view of the semiconductor device during the manufacturing process following FIG. 15.

FIG. 17 is a sectional view along a line B-B in FIG. 16.

FIG. 18 is a sectional view of the semiconductor device of the first embodiment during the manufacturing process.

FIG. 19 is a plan view of a semiconductor device of a first modification of the first embodiment.

FIG. 20 is a plan view of the semiconductor device of the first modification of the first embodiment.

FIG. 21 is a plan view of a semiconductor device of a second modification of the first embodiment.

FIG. 22 is a plan view of the semiconductor device of the second modification of the first embodiment.

FIG. 23 is a plan view of a semiconductor device of a third modification of the first embodiment.

FIG. 24 is a plan view of the semiconductor device of the third modification of the first embodiment.

FIG. 25 is a plan view of a semiconductor device of a fourth modification of the first embodiment.

FIG. 26 is a plan view of the semiconductor device of the fourth modification of the first embodiment.

FIG. 27 is a plan view of a semiconductor device of a fifth modification of the first embodiment.

FIG. 28 is a plan view of the semiconductor device of the fifth modification of the first embodiment.

FIG. 29 is a plan view of the semiconductor device of the fifth modification of the first embodiment.

FIG. 30 is a plan view of the semiconductor device of the fifth modification of the first embodiment.

FIG. 31 is a sectional view of the semiconductor device of the fifth modification of the first embodiment during a manufacturing process of the semiconductor device.

FIG. 32 is a plan view of a semiconductor device of a second embodiment of the invention.

FIG. 33 is a sectional view of the semiconductor device of the second embodiment.

FIG. 34 is a plan view of the semiconductor device of the second embodiment.

FIG. 35 is a sectional view of the semiconductor device of the second embodiment.

FIG. 36 is a sectional view of the semiconductor device of the second embodiment during a manufacturing process of the semiconductor device.

FIG. 37 is a plan view of the semiconductor device during the manufacturing process following FIG. 36.

FIG. 38 is a plan view of a semiconductor device of a third embodiment of the invention.

FIG. 39 is a sectional view of the semiconductor device of the third embodiment.

FIG. 40 is a plan view of the semiconductor device of the third embodiment.

FIG. 41 is a sectional view of the semiconductor device of the third embodiment.

FIG. 42 is a plan view of a semiconductor device of a first modification of the third embodiment.

FIG. 43 is a sectional view of the semiconductor device of the first modification of the third embodiment.

FIG. 44 is a plan view of the semiconductor device of the first modification of the third embodiment.

FIG. 45 is a sectional view of the semiconductor device of the first modification of the third embodiment.

FIG. 46 is a sectional view of a semiconductor device of a second modification of the third embodiment.

FIG. 47 is a sectional view of the semiconductor device of the second modification of the third embodiment.

FIG. 48 is a sectional view of a semiconductor device of a third modification of the third embodiment.

FIG. 49 is a sectional view of the semiconductor device of the third modification of the third embodiment.

FIG. 50 is a sectional view of a semiconductor device of a fourth modification of the third embodiment.

FIG. 51 is a sectional view of the semiconductor device of the fourth modification of the third embodiment.

FIG. 52 is a sectional view of a semiconductor device of a fifth modification of the third embodiment.

FIG. 53 is a sectional view of the semiconductor device of the fifth modification of the third embodiment.

FIG. 54 is a sectional view of a semiconductor device of a sixth modification of the third embodiment.

FIG. 55 is a sectional view of a semiconductor device of the sixth modification of the third embodiment.

FIG. 56 is a sectional view of a semiconductor device of a seventh modification of the third embodiment.

FIG. 57 is a sectional view of the semiconductor device of the seventh modification of the third embodiment.

FIG. 58 is a plan view of a semiconductor device of a comparative example during a manufacturing process of the semiconductor device.

FIG. 59 is a plan view of the semiconductor device of the comparative example during the manufacturing process.

### DETAILED DESCRIPTION

Although each of the following embodiments may be dividedly described in a plurality of sections or embodiments for convenience as necessary, they are not unrelated to one another except for the particularly defined case, and are in a relationship where one is a modification, detailed explanation, supplementary explanation, or the like of part or all of another one. In each of the following embodiments, when the number of elements and others (including the number, a numerical value, amount, and a range) is mentioned, the number is not limited to a specified number except for the particularly defined case and for the case where the number is principally clearly limited to the specified number. In other words, the number may be not less than or not more than the specified number. In each of the following embodiments, a constitutional element (including an element step etc.) of the embodiment is not necessarily indispensable except for the particularly defined case and for the case where the constitutional element is considered to be indispensable in principle. Similarly, in the following embodiment, when a shape of a constitutional element, a positional relationship, and others are described, any configuration substantially closely related to or similar to such a shape or the like should be included except for the particularly defined case and for the case where such a configuration is considered to be not included in principle. The same holds true in the numerical value and the range.

Hereinafter, some embodiments will be described in detail with reference to the accompanying drawings. In all drawings for explaining the embodiments, components having the same function are designated by the same numeral, and duplicated description is omitted. In the following embodiments, the same or similar portion is not repeatedly described in principle except for a particularly required case. In views for explaining the embodiments, a plan view or a perspective view may be hatched for better viewability.

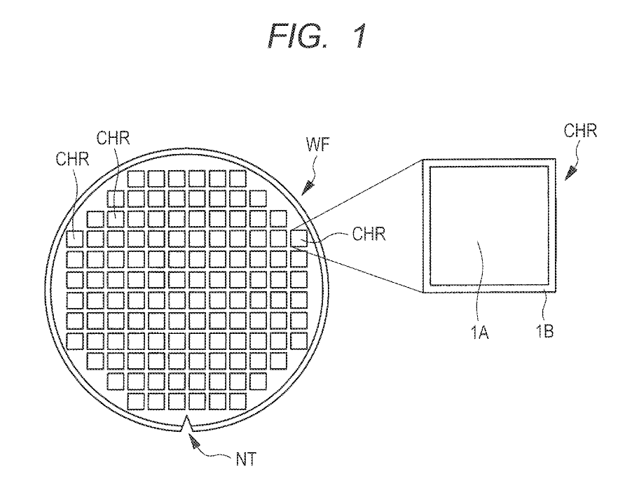

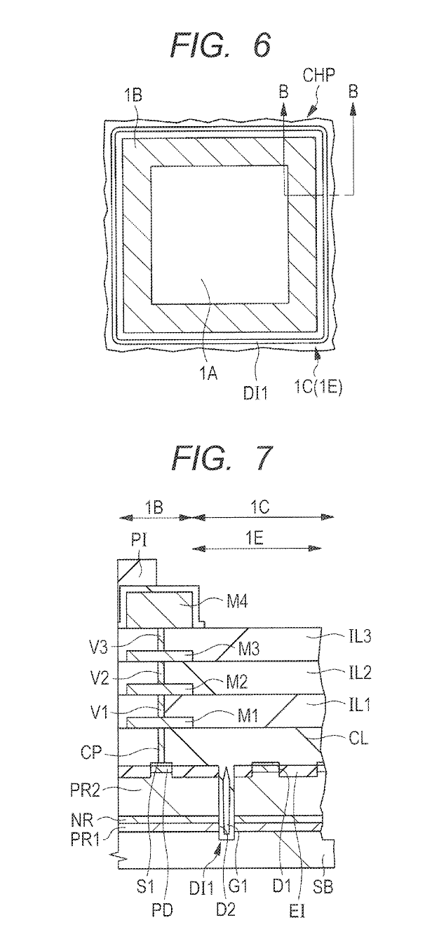

The semiconductor device of this application largely relates to a structure of a semiconductor chip in an area from a seal ring region to a terminal portion of the semiconductor chip. Although the following embodiments may be described using a drawing showing a structure of a semiconductor wafer before singulation by dicing as in FIGS. 1 to 5, the semiconductor device of each embodiment includes not only a semiconductor wafer but also a semiconductor chip after a dicing step (see FIGS. 6 and 7).

### First Embodiment

### Structure of Semiconductor Device

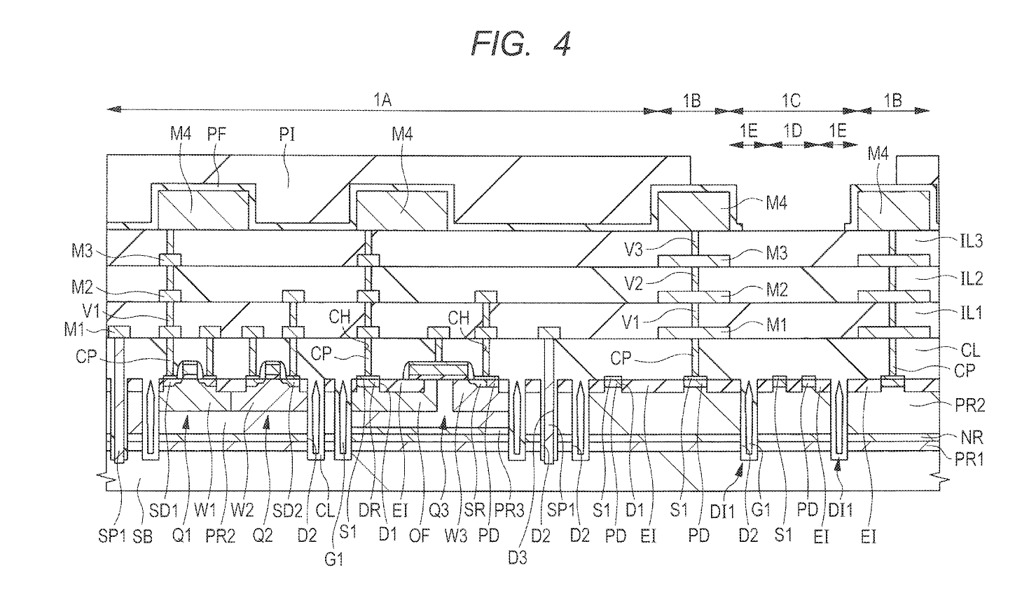

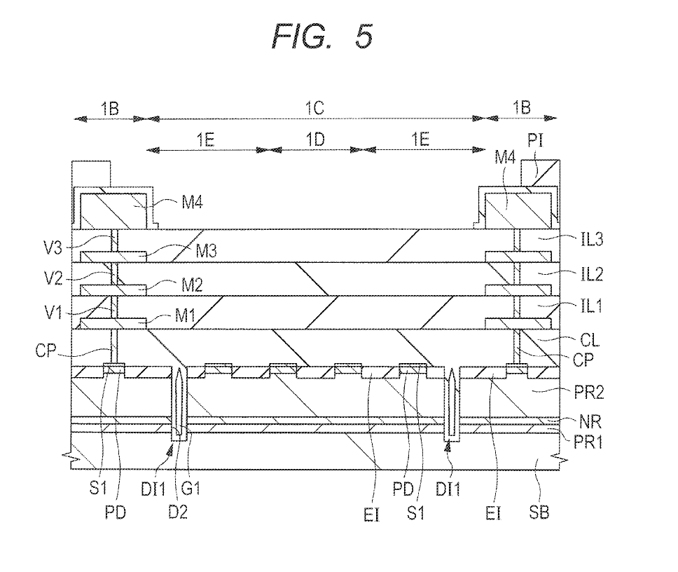

A semiconductor device of a first embodiment is described below with reference to FIGS. 1 to 7. FIGS. 1 to 3 and 6 are each a plan view explaining the semiconductor device of the first embodiment of the invention. FIGS. 4, 5, and 7 are each a sectional view explaining the semiconductor device of the first embodiment. FIG. 4 is the sectional view along a line A-A in FIG. 3. FIG. 7 is the sectional view along a line B-B in FIG. 6. FIG. 4 shows a circuit region 1A, a seal ring region 1B, a scribe region (scribe line) 1C, and the seal ring region 1B in order from the left. FIG. 5 is an enlarged sectional view showing the two seal ring regions 1B in FIG. 4 and the scribe region 1C between the seal ring regions 1B. In the plan views excluding FIG. 1, the seal ring region 1B is hatched for better viewability.

FIG. 1 shows a plan view of a semiconductor wafer WF including the semiconductor device of the first embodiment, and an enlarged plan view of one chip region CHR extracted from among a plurality of chip regions CHR arranged in an array in the main surface of the semiconductor wafer WF. The chip region CHR has a rectangular shape in plan view, and includes the circuit region 1A and the seal ring region 1B. A semiconductor substrate SB is a p-type substrate made of single-crystal silicon (Si), and has a main surface as a first surface on a side where a semiconductor element such as a transistor is formed, and a back surface as a second surface opposite to the first surface.

The semiconductor wafer WF mentioned herein means a disc-like substrate before singulation in one case, or means a stacked structure including the disc-like substrate before singulation, and a semiconductor element and an interconnection layer formed over the substrate in the other case. On the other hand, the semiconductor substrate SB (see FIG. 4) mentioned herein means a substrate configuring the semiconductor wafer WF in one case, or a substrate configuring an individual semiconductor chip in the other case. In each case, the semiconductor substrate SB does not include the semiconductor element and the interconnection layer over the substrate (for example, a silicon substrate).

As shown in FIG. 1, the semiconductor wafer WF (semiconductor substrate SB) having a circular shape in plan view has a notch NT at part of its end portion in plan view. The chip regions CHR are arranged in a matrix in the main surface of the semiconductor wafer WF. Each chip region CHR has a rectangular shape in plan view, and includes the circuit region 1A and the seal ring region 1B. In the circuit region 1A, desired analog and digital circuits are configured by a semiconductor element, an interconnection, a contact plug (conductive coupling part), a substrate contact plug (conductive substrate coupling part), a via (conductive coupling part), and the like. The circuit region 1A in the chip region CHR is located inside the circular seal ring region 1B in plan view.

In the seal ring region 1B, a seal ring including a metal interconnection and a plug (via) is disposed to prevent cracking inside the seal ring region 1B, infiltration of water into the circuit region 1A, and contamination of the circuit region 1A with metal during cutting of the semiconductor wafer WF by a dicing blade. The seal ring region 1B is therefore annually formed in the end portion of the chip region CHR, and protects the circuit region 1A in the middle of the chip region CHR. The seal ring is continuously formed along the seal ring region 1B so as to surround the circuit region 1A in plan view in order to protect the circuit region 1A. That is, the seal ring has an annular plan structure. The seal ring region 1B extending in one direction has a width in a lateral direction of about 6 μm, for example.

The chip regions CHR are arranged side by side in first and second directions along the upper surface of the semiconductor wafer WF. The first direction is orthogonal to the second direction. The first and second directions are each along the main surface of the semiconductor wafer WF and are orthogonal to each other. The chip regions CHR arranged on the upper surface of the semiconductor wafer WF are separated from one another. A region between the adjacent chip regions CHR corresponds to the scribe region 1C. In other words, the scribe region 1C is located on a side opposite to the circuit region 1A with the seal ring region 1B as a boundary. That is, each chip region CHR is surrounded by the scribe region 1C.

The scribe region 1C extends in the first or second direction. Part of the scribe region 1C is cut along the extending direction of the scribe region 1C. That is, the scribe region 1C is partially removed to cut off each chip region CHR. The individual chip region CHR formed by such cutting becomes a semiconductor chip CHP (see FIG. 6). That is, the chip region CHR becomes one semiconductor chip after a dicing step.

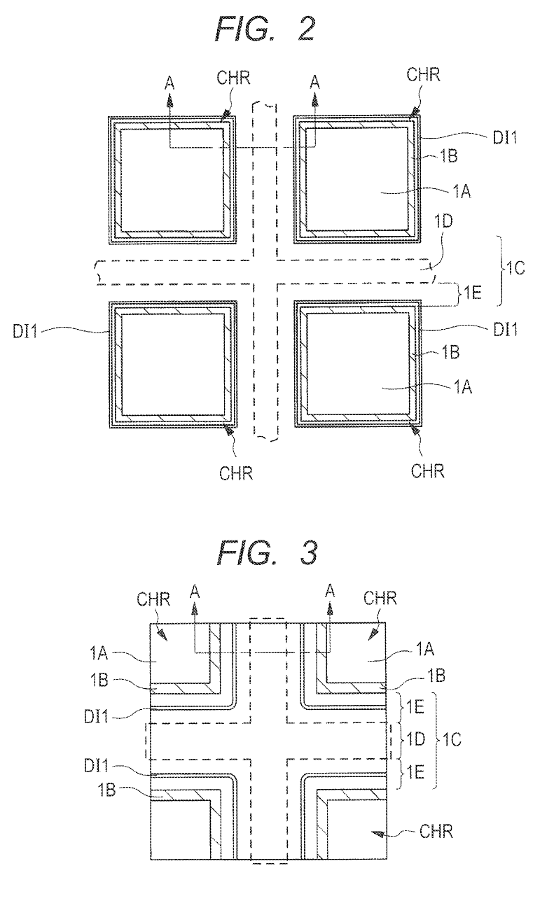

FIG. 2 shows four chip regions CHR arranged in a matrix in an enlarged manner. As shown in FIG. 2, the scribe region 1C includes a cutting region 1D and a peripheral region (residual region, noncutting region) 1E. FIG. 2 and subsequent plan views show the cutting region 1D surrounded by a dashed line. The cutting region 1D is located at the center between the chip regions CHR adjacent in the first or second direction, and extends in the second or first direction. That is, for example, the cutting region 1D between the chip regions CHR adjacent in the first direction extends in the second direction, and the cutting region 1D between the chip regions CHR adjacent in the second direction extends in the first direction.

The peripheral region 1E lies between the cutting region 1D and the chip region CHR, i.e., between the cutting region 1D and the seal ring region 1B. In other words, the cutting region 1D is a region between the peripheral regions 1E separately adjacent to each other. Thus, the peripheral region 1E is in contact with the chip region CHR (seal ring region 1B), while the cutting region 1D is not in contact with the chip region CHR (seal ring region 1B).

The cutting region 1D corresponds to a portion of the scribe region 1C to be cut (removed) by dicing. The peripheral region 1E is corresponds to a portion of the scribe region 1C, which is not cut in the dicing step and remains as an end portion of the semiconductor chip. That is, the peripheral region 1E surrounds the periphery of a region including the circuit region 1A and the seal ring region 1B. In this description, the circuit region 1A and the seal ring region 1B are collectively referred to as chip region CHR assuming the peripheral region 1E is not included in the chip region CHR. However, the peripheral region 1E remains as an end portion of the semiconductor chip, and thus may be considered as part of the chip region CHR.

FIG. 3 shows a portion at which the scribe region 1C extending in the first direction intersects the scribe region 1C extending in the second direction. As shown in FIG. 3, the scribe region 1C extends in the first or second direction, and the scribe region 1C extending in the first direction is orthogonal to the scribe region 1C extending in the second direction. Similarly, the cutting region 1D extending in the first direction is orthogonal to the cutting region 1D extending in the second direction. The scribe region 1C extending in one direction has a width in a lateral direction of about 100 μm, for example.

FIG. 4 shows a sectional view of the semiconductor device of the first embodiment while the scribe region 1C has not been cut. FIG. 4 is a sectional view along a lateral direction of each of the seal ring region 1B, the scribe region 1C, the cutting region 1D, and the peripheral region 1E. The seal ring region 1B exists between the scribe region 1C and the circuit region 1A. The peripheral region 1E exists between the seal ring region 1B and the cutting region 1D.

As shown in FIG. 4, the semiconductor device of the first embodiment has a stacked substrate including the semiconductor substrate SB and an epitaxial layer (semiconductor layer) formed by an epitaxial growth process on the semiconductor substrate SB. Hereinafter, the substrate including the semiconductor substrate SB and the epitaxial layer on the semiconductor substrate SB is referred to as stacked substrate. Since the semiconductor substrate SB and the epitaxial layer are each made of a semiconductor, the stacked substrate may be referred to as semiconductor substrate. The epitaxial layer includes a p-type semiconductor region PR1, an n-type embedded region NR, and a p-type semiconductor region PR2 formed in order over the semiconductor substrate SB.

A p-type low-withstand-voltage transistor Q1, an n-type low-withstand-voltage transistor Q2, and an n-type high-withstand-voltage transistor Q3 are formed over the p-type semiconductor region PR2 in the circuit region 1A. Each of the p-type low-withstand-voltage transistor Q1, the n-type low-withstand-voltage transistor Q2, and the n-type high-withstand-voltage transistor Q3 is a metal oxide semiconductor field effect transistor (MOSFET) having the upper surface of the p-type semiconductor region PR2, i.e., the upper surface of the stacked surface, as a channel region. Each of the p-type low-withstand-voltage transistor Q1 and the n-type low-withstand-voltage transistor Q2 is a MOS field effect transistor driven by a lower voltage than the n-type high-withstand-voltage transistor Q3. The n-type high-withstand-voltage transistor Q3 is a MOS field effect transistor having a withstand voltage of 45 V, for example. FIG. 4 shows the p-type low-withstand-voltage transistor Q1, the n-type low-withstand-voltage transistor Q2, and the n-type high-withstand-voltage transistor Q3 in order from the left.

The p-type low-withstand-voltage transistor Q1, the n-type low-withstand-voltage transistor Q2, and the n-type high-withstand-voltage transistor Q3 are isolated from one another by an element isolation region EI including an insulating film buried in a trench (isolation trench) D1 formed in the upper surface of the stacked substrate. The element isolation region EI is mainly made of silicon oxide, for example. The element isolation region EI is formed in any of the circuit region 1A, the seal ring region 1B, and the scribe region 1C. A plurality of pseudo element isolation regions EI, which are not used for element isolation, are formed side by side in the scribe region 1C. That is, each pseudo element isolation region EI is disposed as a dummy pattern in addition to an active region in the scribe region 1C outside the seal ring region 1B in order to improve flatness during formation of the element isolation regions EI.

An n-type well W1 and a p-type well W2, each deeper than the trench D1, are adjacently formed in the upper surface of the p-type semiconductor region PR2. The p-type low-withstand-voltage transistor Q1 is formed on the n-type well W1, and the n-type low-withstand-voltage transistor Q2 is formed on the p-type well W2. The element isolation region EI is a relatively shallow element isolation part, and has a shallow trench isolation (STI) structure, for example.

The p-type low-withstand-voltage transistor Q1 has a gate electrode formed over the stacked substrate with a gate insulating film in between. Side surfaces on both sides of the gate electrode in a gate length direction are each covered with a sidewall including an insulating film. The p-type low-withstand-voltage transistor Q1 has a pair of source-drain regions SD1 formed across the upper surface of the n-type well W1 directly below the gate electrode. Each source-drain region SD1 is a p-type semiconductor region, and is formed at a shallower depth than the element isolation region EI. Each of the pair of source-drain regions SD1 includes an extension region and a diffusion region adjacent to each other. The gate insulating film includes, for example, a silicon oxide film, a silicon nitride film, or a stacked structure of such films. The gate electrode includes a polysilicon film.

The n-type low-withstand-voltage transistor Q2 has a gate electrode formed over the stacked substrate with a gate insulating film in between. Side surfaces on both sides of the gate electrode in a gate length direction are each covered with a sidewall including an insulating film. The n-type low-withstand-voltage transistor Q2 has a pair of source-drain regions SD2 formed across the upper surface of the p-type well W2 directly below the gate electrode. Each of the source-drain regions SD2 is an n-type semiconductor region, and is formed at a shallower depth than the element isolation region EI. The source-drain region SD2 includes an extension region and a diffusion region adjacent to each other. The gate insulating film includes, for example, a silicon oxide film, a silicon nitride film, or a stacked structure of such films. The gate electrode includes a polysilicon film.

The n-type high-withstand-voltage transistor Q3 has a gate electrode formed over the stacked substrate with the element isolation region EI and a gate insulating film in between. Side surfaces on both sides of the gate electrode in a gate length direction are each covered with a sidewall including an insulating film. The length in the gate length direction of the n-type high-withstand-voltage transistor Q3 is longer than the length in the gate length direction of each of the p-type low-withstand-voltage transistor Q1 and the n-type low-withstand-voltage transistor Q2. The thickness of the gate insulating film of the n-type high-withstand-voltage transistor Q3 is equal to or larger than the thickness of the gate insulating film of each of the p-type low-withstand-voltage transistor Q1 and the n-type low-withstand-voltage transistor Q2. The gate insulating film includes, for example, a silicon oxide film, a silicon nitride film, or a stacked structure of such films. The gate electrode includes a polysilicon film.

The n-type high-withstand-voltage transistor Q3 has a source region SR and a drain region DR formed across the upper surface of the p-type semiconductor region PR2 directly below the gate electrode. The source region SR and the drain region DR are each an n-type semiconductor region, and formed at a shallower depth than the element isolation region EI. The element isolation region EI buried in the trench D1 is provided between the drain region DR and the p-type semiconductor region PR2 directly below the gate electrode, and an n-type offset region OF is formed in the surface of the p-type semiconductor region PR2 adjacent to a side surface and a bottom surface of the trench D1.

The source region SR is formed in the upper surface of a p-type well W3 formed in the upper surface of the p-type semiconductor region PR2, and a p-type diffusion region PD adjacent to the source region SR is formed in the upper surface of a p-type well W3. The n-type offset region OF and the p-type well W3 are separated from each other directly below the gate electrode. A p-type embedded region PR3 is formed between the n-type embedded region NR and the p-type semiconductor region PR2 directly below the n-type high-withstand-voltage transistor Q3. The source region SR includes an extension region and a diffusion region adjacent to each other.

The diffusion region configuring each of the source-drain region SD1, the source-drain region SD2, and the source region SR has a higher impurity concentration than the extension region adjacent to the diffusion region. In this way, each of the source-drain region SD1, the source-drain region SD2, and the source region SR has a lightly doped drain (LDD) structure including the diffusion region having a high impurity concentration and the extension region having a low impurity concentration.

While the upper surface of the source-drain region of each of the p-type low-withstand-voltage transistor Q1, the n-type low-withstand-voltage transistor Q2, and the n-type high-withstand-voltage transistor Q3 is exposed from the gate electrode and from the sidewall, the upper surface is covered with a silicide layer S1. The upper surface of each gate electrode is also covered with the silicide layer S1. The silicide layer S1 is a conductor layer formed through a reaction of a metal such as, for example, titanium (Ti), cobalt (Co), or nickel (Ni) with silicon (Si). In the cutting region 1D, the p-type diffusion region PD is formed in the upper surface of the p-type semiconductor region PR2 exposed from the element isolation region EI. In an undepicted portion of the cutting region 1D, the upper surface of each of the element isolation region EI and the p-type diffusion region PD is covered with an insulating film. The insulating film, which includes, for example, a silicon oxide film or a silicon nitride film, is provided to prevent a silicide layer from being formed in the upper surface of the p-type diffusion region PD.

An interlayer insulating film (contact interlayer film) CL is formed over the stacked substrate so as to cover the p-type low-withstand-voltage transistor Q1, the n-type low-withstand-voltage transistor Q2, and the n-type high-withstand-voltage transistor Q3. The interlayer insulating film CL mainly includes, for example, a silicon nitride film or a silicon oxide film, and has a planarized upper surface. Specifically, the interlayer insulating film CL includes a boro phospho tetra ethyl ortho silicate (BP-TEOS) film. The upper surface of the interlayer insulating film CL is planarized. In the circuit region 1A, a plurality of contact holes (coupling holes) CH are formed from the upper surface to the lower surface of the interlayer insulating film CL so as to penetrate the interlayer insulating film CL, and a plurality of contact plugs (conductive coupling parts) CP including a conductor film buried in the respective contact holes CH are formed over the stacked substrate. The contact plug CP is formed of a metal film (conductor film) mainly including a tungsten (W) film.

Each of the contact plugs CP is coupled to one of the p-type low-withstand-voltage transistor Q1, the n-type low-withstand-voltage transistor Q2, and the n-type high-withstand-voltage transistor Q3, for example. That is, each contact plug CP is coupled via the silicide layer S1 to the upper surface of one of the gate electrode of the p-type low-withstand-voltage transistor Q1, the gate electrode of the n-type low-withstand-voltage transistor Q2, the gate electrode of the n-type high-withstand-voltage transistor Q3, the source-drain region SD1, the source-drain region SD2, the source region SR, and the drain region DR. The silicide layer S1 reduces a coupling resistance between each gate electrode, the source-drain region SD1, the source-drain region SD2, the source region SR, or the drain region DR and the contact plug CP.

Each of the contact plugs CP has, for example, a cylindrical shape, and has a diameter, i.e., an average width of about 0.1 μm, for example, in a direction (lateral direction, horizontal direction) along the main surface of the semiconductor substrate. FIG. 4 does not show the contact plug CP coupled to the gate electrode of each of the p-type low-withstand-voltage transistor Q1 and the n-type low-withstand-voltage transistor Q2. The contact plug CP is not formed in the scribe region 1C, but also not formed in the seal ring region 1B in the first embodiment. The upper surface of each contact plug CP and the upper surface of the interlayer insulating film CL are planarized in substantially the same plane.

A first interconnection layer, which includes a plurality of interconnections M1 and an interlayer insulating film IL1 covering the side surface and the upper surface of each interconnection M1, is formed on the interlayer insulating film CL. The first interconnection layer includes vias V1 that are coupled to the upper surfaces of the respective interconnections M1 while penetrating the interlayer insulating film IL1. The interlayer insulating film IL1 includes, for example, a silicon oxide film, the interconnection M1 is mainly made of, for example, aluminum (Al), and the via V1 is mainly made of, for example, tungsten (W). Part of the lower surface of the interconnection M1 is coupled to the upper surface of the contact plug CP. The lateral width of the interconnection M1 is larger than the lateral width of each of the contact plug CP and the via V1. The upper surface of each via V1 and the upper surface of the interlayer insulating film IL1 are planarized in substantially the same plane.

A second interconnection layer and a third interconnection layer, each having a configuration similar to that of the first interconnection layer, are stacked in order on the first interconnection layer. That is, the second interconnection layer includes interconnections M2 coupled to the upper surfaces of the vias V1, an interlayer insulating film IL2 covering the interconnections M2, and vias V2 that are coupled to the upper surfaces of the interconnections M2 while penetrating the interlayer insulating film IL2. The third interconnection layer includes interconnections M3 coupled to the upper surfaces of the vias V2, an interlayer insulating film IL3 covering the interconnections M3, and vias V3 that are coupled to the upper surfaces of the interconnections M3 while penetrating the interlayer insulating film IL3. A plurality of interconnections M4 coupled to the upper surfaces of the vias V3 are formed on the third interconnection layer. The interconnections M4 form an interconnection pattern mainly made of aluminum (Al).

The upper surface and the side surface of each interconnection M4 and the upper surface of the interlayer insulating film IL3 are covered with a passivation film PF and a polyimide film PI formed in order on the interlayer insulating film IL3. However, the upper surface of the interlayer insulating film IL3 in the scribe region 1C is exposed from the passivation film PF excluding the end portion of the scribe region 1C. The polyimide film PI is not formed in the scribe region 1C. In an undepicted bonding pad part, the passivation film PF and the polyimide film PI are removed to allow a bonding wire or the like to be coupled to the upper surface of the interconnection M4.

Although a case where the contact plugs CP, the vias V1 to V3, and the substrate contact plugs SP1 are mainly made of tungsten has been described herein, the contact plugs CP and the vias V1 to V3 may be mainly made of, for example, copper (Cu), or a polysilicon film containing phosphorus (P) introduced therein. The substrate contact plug SP1 may be formed of, for example, a barrier conductor film made of tantalum (Ta) or tantalum nitride (TaN) and a main conductor film made of copper (Cu), or may be formed of a polysilicon film containing phosphorus (P) introduced therein. The number of interconnection layers may be more or less than four.

The interconnections M1 to M4, the vias V1 to V3, and the contact plugs CP in the circuit region 1A are electrically coupled to one another. That is, the interconnection M4 is electrically coupled to a semiconductor element through the via V3, the interconnection M3, the via V2, the interconnection M2, the via V1, the interconnection M1, the contact plug CP, and the silicide layer S1, so that a circuit is configured.

A plurality of trenches D2 are formed in the respective upper surfaces of some of the element isolation regions EI so as to extend from the upper surface of each element isolation region EI to an intermediate depth of the semiconductor substrate SB. That is, each trench D2 penetrates the element isolation region EI, the p-type semiconductor region PR2, the n-type embedded region NR, and the p-type semiconductor region PR1. In other words, the trench D2 is formed in the upper surface of the stacked substrate. The depth from the uppermost surface of the stacked substrate to the bottom surface of the trench D2 is deeper than the depth from the uppermost surface of the stacked substrate to the bottom surface of the trench D1. That is, the depth of the trench D2 is larger than the depth of the trench D1. Part of the interlayer insulating film CL is buried in part of the inside of the trench D2.

Some of the trenches D2 are used as element isolation parts, and a gap (hollow part) surrounded by the interlayer insulating film CL exists inside each of such trenches D2. The bottom surface and the side surface of that trench D2 are covered with the interlayer insulating film CL. Hereinafter, the trench D2 used as the element isolation part may be referred to as deep trench isolation (DTI) structure. For example, the DTI structure is formed to electrically isolate a complementary metal oxide semiconductor (CMOS) including the p-type low-withstand-voltage transistor Q1 and the n-type low-withstand-voltage transistor Q2 from the n-type high-withstand-voltage transistor Q3. In addition, for example, the DTI structure is formed to prevent a semiconductor element from being electrically coupled to the following substrate contact plug SP1 in a lateral direction. The DTI structure has a structure having the gap G1, and thus has a higher insulation performance than a structure in which the trench D2 is completely filled with the interlayer insulating film CL.

The substrate contact plug (conductive substrate coupling part) SP1 is buried in some of the trenches D2. That is, some of the trenches D2 are filled with part of the interlayer insulating film CL, a trench D3 as a contact hole (substrate contact trench, coupling hole) is formed in each of such trenches D2 so as to extend from the upper surface of the interlayer insulating film CL to the bottom surface of the trench D2 through the trench D2, and the trench D3 is filled with the substrate contact plug SP1 including a conductor film coupled to the upper surface of the semiconductor substrate SB. That is, the trench (substrate contact trench, contact hole, coupling hole) D3 is formed separately from the side surface of the trench D2 within a range in which the trench D3 overlaps the trench D2 in plan view. Part of the interlayer insulating film CL is formed between the side surface of the trench D3 and the side surface of the trench D2.

The substrate contact plug SP1 is formed of a metal film (conductor film) mainly including a tungsten (W) film. Although tungsten (W) is exemplified as a material of the substrate contact plug SP1, the material, which is buried in the trench D3 to configure the substrate contact plug SP1, may be copper (Cu) or polysilicon, for example.

Part of the trench D3 is formed by the gap G1 in the trench D2. The substrate contact plug SP1 is formed from the height of the upper surface of the interlayer insulating film CL to the bottom surface of the trench D2 by filling the gap G1 in the trench D2 with the conductor film. The substrate contact plug SP1 is electrically coupled to the semiconductor substrate SB at the bottom surface of the trench D2. The trench D3 is formed from above the trench D2 to the intermediate depth of the semiconductor substrate SB as a position deeper than the bottom surface of the trench D2. That is, the depth from the uppermost surface of the stacked substrate to the bottom surface of the trench D3 is deeper than the depth from the uppermost surface of the stacked substrate to the bottom surface of the trench D2. In other words, the depth of the trench D3 is larger than the depth of the trench D2. The trench D2 has a width in a lateral direction of about 0.8 μm, for example. The trench D3 and the substrate contact plug SP1 each have a width in a lateral direction of about 0.5 μm, for example. The width of each of the trench D3 and the substrate contact plug SP1 is larger than the diameter of the contact plug CP.

In the circuit region 1A, a plurality of substrate contact plugs SP1 are provided as conductive coupling parts to apply a predetermined voltage to the semiconductor substrate SB. The upper surface of each substrate contact plug SP1 is coupled to the lower surface of the interconnection M1. That is, the substrate contact plug SP1 is electrically coupled to each of the semiconductor substrate SB and the interconnection M1 so that a circuit is configured.

FIG. 5 illustrates a section of the scribe region 1C in an enlarged manner. As shown in FIG. 5, in the peripheral region 1E, the element isolation region EI buried in each trench D1 is formed in the upper surface of the stacked substrate. In one major feature of the first embodiment, the trench D2 is formed in the upper surface of the element isolation region EI from the upper surface of the element isolation region EI to the intermediate depth of the semiconductor substrate SB, and the gap G1 exists within the trench D2 via the interlayer insulating film CL. A DTI structure, which includes the trench D2 in the peripheral region 1E and the interlayer insulating film CL and the gap G1 in that trench D2, is referred to as dummy isolation part DI1. The dummy isolation part DI1 is a pseudo isolation part that does not electrically isolate between semiconductor elements unlike the DTI structure, which includes the trench D2 and the gap G1 formed in the circuit region 1A shown in FIG. 4.

As described later, the dummy isolation part DI1 is a structure to protect the chip region CHR from chipping or cracking caused by a dicing step. Specifically, in the main feature of the first embodiment, the dummy isolation part DI1 is provided in the peripheral region 1E to use not only the seal ring but also the peripheral region 1E as part of the scribe region 1C in order to protect the circuit region 1A from chipping or cracking.

The structures of the trench D2 and the gap G1 in the peripheral region 1E are the same as the structures of the trench D2 and the gap G1, respectively, in the circuit region 1A. Specifically, the trench D2 in the peripheral region 1E penetrates the element isolation region EI, the p-type semiconductor region PR2, the n-type embedded region NR, and the p-type semiconductor region PR1. In other words, the trenches D2 are formed in the upper surface of the stacked substrate. The depth from the uppermost surface of the stacked substrate to the bottom surface of the trench D2 is larger than the depth from the uppermost surface of the stacked substrate to the bottom surface of the trench D1. That is, the depth of the trench D2 in the peripheral region 1E is larger than the depth of the trench D1.

However, as shown in FIGS. 2 and 3, the dummy isolation part DI1 is formed annually along a layout of the peripheral region 1E, and surrounds the circuit region 1A and the seal ring region 1B in plan view. That is, the trench D2 and the gap G1 in the peripheral region 1E are formed annually so as to surround the chip region CHR in plan view. In other words, the trench D2 and the gap G1 in the peripheral region 1E extend in a depth direction of FIG. 4. As shown in FIGS. 2 and 3, a bent part of the dummy isolation part DI1 in the vicinity of a corner of the chip region CHR is in a layout to be bent at 90°. However, the bent part is actually rounded in a photolithography step of a manufacturing process, and thus does not have a perfect right angle.

In the seal ring region 1B, the interconnections M1 to M4 and the vias V1 to V3 are formed, and such conductor films are electrically coupled to the contact plug CP coupled to the lower surface of the interconnection M1. The lower surface of the contact plug CP is coupled to the p-type diffusion region PD via the silicide layer S1. However, each contact plug CP, the interconnections M1 to M4, and the vias V1 to V3 in the seal ring region 1B are not electrically coupled to the semiconductor element such as the p-type low-withstand-voltage transistor Q1, the n-type low-withstand-voltage transistor Q2, or the n-type high-withstand-voltage transistor Q3 in the circuit region 1A and to the interconnections M1 to M4 in the circuit region 1A. In other words, the contact plug CP, the interconnections M1 to M4, and the vias V1 to V3 in the seal ring region 1B do not configure a circuit.

No substrate contact plug SP1 is formed in each of the seal ring region 1B and the scribe region 1C, and the DTI structure including the trench D2 is not formed in the cutting region 1D. The trench D2 in the circuit region 1A extends up to the intermediate depth of the semiconductor substrate SB through the interlayer insulating film CL and the element isolation region EI. Each of the trenches D2 and D3 is formed at a position overlapping the trench D1 in plan view.

The seal ring region 1B is provided to protect the circuit region 1A in the middle of the semiconductor chip CHP, and is thus annually formed so as to surround the periphery of the circuit region 1A in plan view. In other words, the seal ring region 1B is rectangularly formed along the four sides as the periphery of the semiconductor chip CHP having a rectangular shape in plan view. That is, the seal ring region 1B is formed in a frame shape in plan view. Each contact plug CP, the interconnections M1 to M4, and the vias V1 to V3 configuring the seal ring, and the silicide layer S1 and the p-type diffusion region PD directly below that contact plug CP are also annually formed along the extending direction of the seal ring region 1B. The dummy isolation part DI1 formed so as to surround the seal ring region 1B also has an annular rectangular shape in plan view. Specifically, the dummy isolation part DI1 has four extending parts. The dummy isolation part DI1 has a structure where such four extending parts are connected to one another in the vicinity of the respective corners of the semiconductor chip CHP, and is continuously formed so as to surround the circuit region 1A.

In the semiconductor device of the first embodiment, the p-type low-withstand-voltage transistor Q1, the n-type low-withstand-voltage transistor Q2, the n-type high-withstand-voltage transistor Q3, and undepicted passive elements in the circuit region 1A are electrically coupled to one another using the contact plugs CP, the interconnections M1 to M4, and the vias V1 to V3, so that desired analog and digital circuits are configured in the circuit region 1A. The first embodiment has been described with a configuration where a metal film such as an interconnection is not formed in the scribe region 1C. However, a dummy pattern formed by a gate electrode or a metal interconnection, an alignment mark used for producing a semiconductor device, or a mark used for evaluation of any of various characteristics may be formed in the scribe region 1C, as long as such a pattern or mark does not adversely affect dicing performance. However, the DTI structure is not formed in the cutting region 1D.

FIGS. 6 and 7 show one of a plurality of semiconductor chips CHP produced as a result of singulation through a dicing step performed on the semiconductor wafer WF (see FIG. 1). FIG. 7 shows an end portion of the semiconductor chip, including the seal ring region 1B and the peripheral region (residual region) 1E adjacent to the seal ring region 1B.

In the dicing step, a dicing blade is used to cut the cutting region 1D (see FIG. 3) in the scribe region (scribe line) 1C of the semiconductor wafer, thereby the semiconductor wafer is divided into individual semiconductor chips. In the dicing step, a slit is first formed from the upper side to the intermediate depth of the semiconductor wafer using a dicing blade having a relatively large cutting width. Subsequently, a substrate portion under the slit is cut using a dicing blade having a relatively small cutting width, so that the semiconductor wafer is cut. As shown in FIG. 7, therefore, differences in level are formed in a section of an end portion (side surface) of the semiconductor chip. That is, the lower end portion of the side surface of the semiconductor chip protrudes outward.

As shown in FIG. 6, the semiconductor chip CHP mainly includes the chip region CHP (see FIG. 2), and further includes the peripheral region 1E as part of the scribe region 1C at its end. In other words, the peripheral region 1E becomes an end portion of the semiconductor chip CHP on an outer side compared with the seal ring region 1B.

The width of a dicing blade used in the dicing step is smaller than the width in a lateral direction of the scribe region 1C. Hence, even if the cutting region 1D is cut in the dicing step, the peripheral region 1E as part of the scribe region 1C remains at the end of the semiconductor chip CHP. That is, the dummy isolation part DI1 formed in the peripheral region 1E is not cut, i.e., remains. Since a cutting range varies in the dicing step, the seal ring region 1B is necessary to be avoided from being cut; hence, only the cutting region 1D is cut in the dicing step instead of entirely cutting the scribe region 1C. The cutting region 1D may partially remain in the semiconductor chip CHP, or the peripheral region 1E may be partially cut due to a variation in the cutting range. Even in such a case, the dummy isolation part DI1 is not cut.

### Method of Manufacturing Semiconductor Device

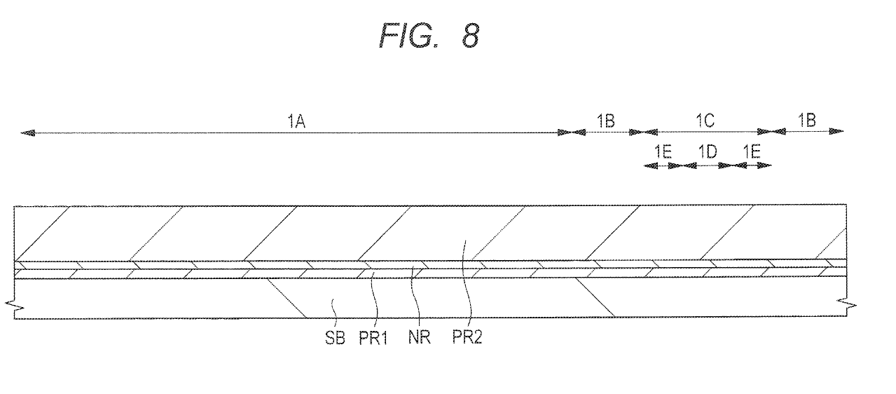

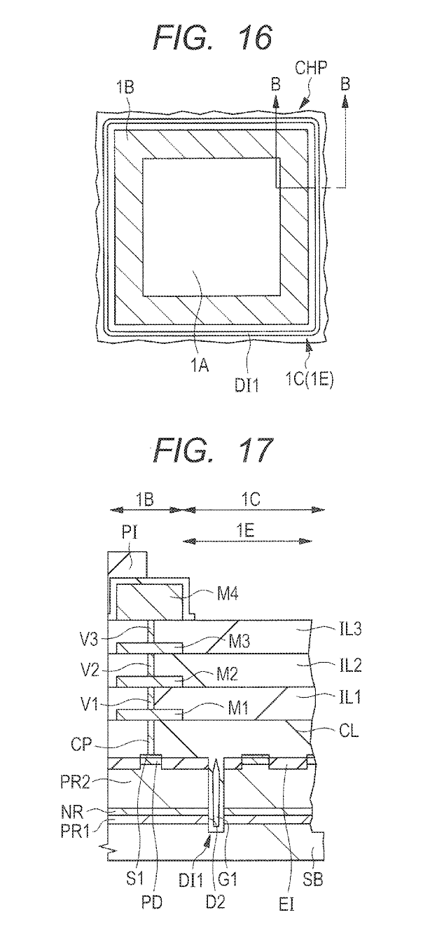

A method of manufacturing the semiconductor device of the first embodiment is described below with reference to FIGS. 1 and 8 to 17. FIGS. 8 to 15 and 17 are each a sectional view of the semiconductor device of the first embodiment during a manufacturing process of the semiconductor device. FIG. 16 is a plan view of the semiconductor device of the first embodiment during the manufacturing process. Each of FIGS. 8 to 15 shows the circuit region 1A, the seal ring region 1B, the scribe region (scribe line) 1C, and the seal ring region 1B in order from the left. That is, the scribe region 1C exists between the two seal ring regions 1B. FIG. 17 is a sectional view along a line B-B in FIG. 16. FIG. 17 shows the seal ring region 1B and the peripheral region 1E in the end portion of the semiconductor chip.

The scribe region 1C lies between the two seal ring regions 1B, and includes two peripheral regions 1E and the cutting region 1D between the peripheral regions 1E. A part (cutting region 1D) of the scribe region 1C is cut for singulation of the semiconductor wafer in a manufacturing process of the semiconductor device. The seal ring region 1B is located in a marginal portion of a semiconductor chip region to be the semiconductor chip produced through the dicing step. In the circuit region 1A, an element, an interconnection, and the like are formed to configure the circuit.

In the manufacturing process of the semiconductor device, first, as shown in FIGS. 1 and 8, provided is a p-type semiconductor substrate SB i.e., the semiconductor wafer WF made of single-crystal silicon (Si), for example. The semiconductor substrate SB has a main surface as a first surface on which the semiconductor elements such as a photodiode and a transistor are formed in a later step, and a back surface as a second surface opposite to the main surface. An epitaxial layer having a lower concentration of a p-type impurity than the semiconductor substrate SB is formed on the semiconductor substrate SB. The epitaxial layer is a p-type semiconductor layer formed by an epitaxial growth process. The semiconductor substrate SB and the epitaxial layer collectively configure the stacked substrate.

Subsequently, an n-type impurity is implanted into the epitaxial layer by, for example, an ion implantation process to form the n-type embedded region NR at an intermediate depth of the epitaxial layer. The epitaxial layer below the n-type embedded region NR corresponds to the p-type semiconductor region PR1. Subsequently, a p-type impurity is implanted into the epitaxial layer by, for example, an ion implantation process to form the p-type semiconductor region PR2 in the epitaxial layer from the upper surface of the epitaxial layer to the top of the n-type embedded region NR. As a result, the p-type semiconductor region PR1, the n-type embedded region NR, and the p-type semiconductor region PR2 are formed in order over the semiconductor substrate SB. The impurity concentration of each of the p-type semiconductor regions PR1 and PR2 is lower than the impurity concentration of the semiconductor substrate SB.

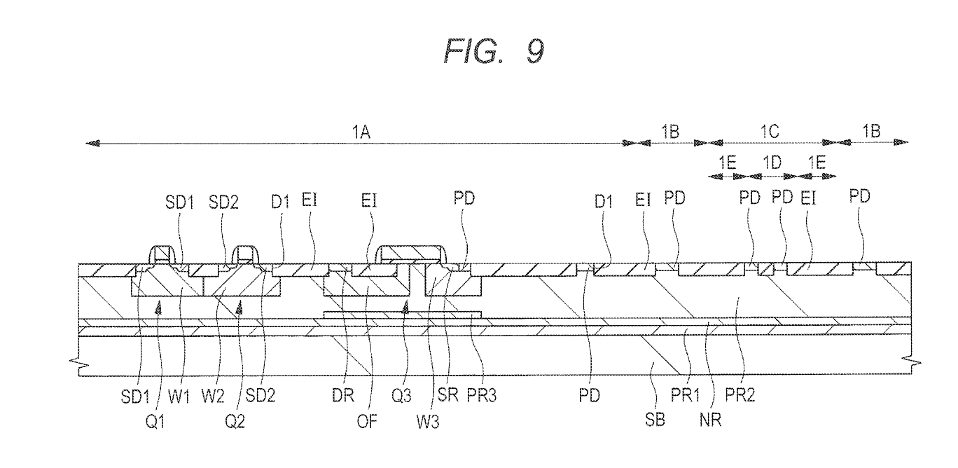

Subsequently, as shown in FIG. 9, a plurality of trenches D1 are formed in the upper surface of the p-type semiconductor region PR2 by a dry etching process using an undepicted hard mask. Subsequently, the element isolation region EI including an insulating film is formed so as to fill each trench D1. Each element isolation region EI, including, for example, a silicon oxide film, has an STI structure. A plurality of element isolation regions EI are formed in each of the circuit region 1A, the seal ring region 1B, and the scribe region 1C. In the scribe region 1C, the element isolation region EI is formed in each of the cutting region 1D and the peripheral region 1E.

Subsequently, an n-type impurity is implanted into the upper surface of the p-type semiconductor region PR2 in the circuit region 1A by, for example, an ion implantation process to form an n-type well W1 in the upper surface of the p-type semiconductor region PR2. In addition, a p-type impurity is implanted into the upper surface of the p-type semiconductor region PR2 in the circuit region 1A by, for example, an ion implantation process to form a p-type well W2 in the upper surface of the p-type semiconductor region PR2. Furthermore, a p-type impurity and an n-type impurity are implanted into the upper surface of the p-type semiconductor region PR2 in the circuit region 1A by, for example, an ion implantation process to form the n-type offset region OF and the p-type well W3 in the upper surface of the p-type semiconductor region PR2. In addition, a p-type impurity is implanted into the region in which the n-type offset region OF and the p-type well W3 are formed, i.e., the n-type embedded region NR in the high-withstand-voltage transistor formation region by, for example, an ion implantation process to form the p-type embedded region PR3. Heat treatment in, for example, nitrogen atmosphere is performed each time after performing the ion implantation steps forming the n-type well W1, the n-type offset region OF, and the p-type wells W2 and W3.

Subsequently, the p-type low-withstand-voltage transistor Q1 is formed on the n-type well W1, the n-type low-withstand-voltage transistor Q2 is formed on the p-type well W2, and the n-type high-withstand-voltage transistor Q3 is formed on the p-type semiconductor region PR2 in which the n-type offset region OF and the p-type well W3 are formed. Since such transistors do not have the main feature of the first embodiment, the manufacturing process of the transistors is briefly described below.

In the formation steps of such transistors, first, a gate insulating film including a silicon oxide film, a silicon nitride film, or a stacked film of those films is formed in the upper surface of the stacked substrate by a thermal oxidation process, for example. Subsequently, a plurality of gate electrodes are formed on the gate insulating film. For each gate electrode, a polysilicon film is deposited by, for example, a chemical vapor deposition (CVD) process, and then separately formed into an n type or a p type by an ion implantation process or the like. Subsequently, the polysilicon film and the gate insulating film are each processed into a desired pattern using a photolithography technique and a dry etching process. As a result, various gate electrodes including the polysilicon film are formed.

Subsequently, a p-type impurity is implanted into the upper surface of the n-type well W1 by an ion implantation process to form the pair of source-drain regions SD1 including a p-type semiconductor region. An n-type impurity is implanted into the upper surface of the p-type well W2 by an ion implantation process to form the pair of source-drain regions SD2 including an n-type semiconductor region. An n-type impurity is implanted into the upper surface of the n-type offset region OF by an ion implantation process to form the drain region DR including an n-type semiconductor region. An n-type impurity is implanted into the upper surface of the p-type well W3 by an ion implantation process to form the source region SR including an n-type semiconductor region. A p-type impurity is implanted into the upper surface of the p-type well W3 adjacent to the source region SR by an ion implantation process to form the p-type diffusion region PD including a p-type semiconductor region.

The p-type diffusion region PD including the p-type semiconductor region is also formed in the upper surface of the p-type semiconductor region PR2 exposed from the element isolation region EI in each of the seal ring region 1B and the cutting region 1D. Heat treatment in nitrogen atmosphere is performed each time after performing the ion implantation steps forming the source-drain regions SD1 and SD2, the source region SR, the drain region DR, and the p-type diffusion region PD. Part of the p-type diffusion region PD in the seal ring region 1B is formed so as to surround the circuit region 1A in plan view, and has an annular plan layout.

The source-drain regions SD1 and SD2 and the source region SR are each formed by the extension region and the diffusion region separately formed by a two-stage implantation step. The extension region has a lower impurity concentration than the diffusion region, and is located on a side close to the gate electrode configuring the transistor while having a shallow depth.

In this way, it is possible to form the p-type low-withstand-voltage transistor Q1 including the source-drain regions SD1 and the gate electrode over the n-type well W1, the n-type low-withstand-voltage transistor Q2 including the source-drain regions SD2 and the gate electrode over the p-type well W2, and the n-type high-withstand-voltage transistor Q3 including the source region SR, the drain region DR, and the gate electrode. The sidewall including an insulating film covering the side surface of each gate electrode is formed after formation of the extension region and before formation of the diffusion region.

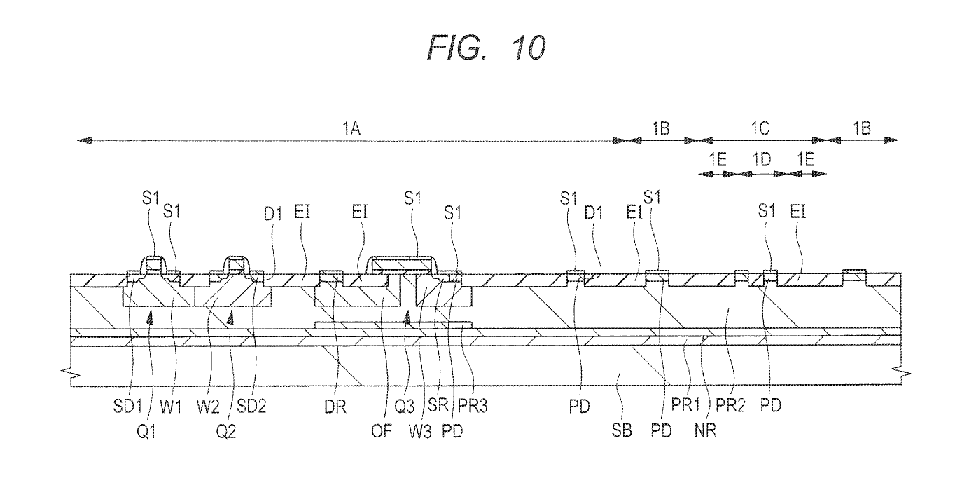

Subsequently, as shown in FIG. 10, a known silicide process is performed to form a silicide layer S1 covering the exposed diffusion regions and the exposed gate electrodes. Specifically, first, the upper surface of the p-type diffusion region PD exposed in the cutting region 1D and the upper surface of the element isolation region EI in the cutting region 1D are covered by an undepicted insulating film to prevent the silicide layer S1 from being formed in the cutting region 1D in an undepicted region. The insulating film is a silicide protection film including, for example, a silicon oxide film or a silicon nitride film formed by a CVD process, for example.

Subsequently, a metal film made of titanium (Ti), cobalt (Co), or nickel (Ni) is used over the entire surface of the semiconductor substrate SB using a sputtering process, for example. The thickness of the metal film is about several tens of nanometers, for example. Subsequently, the stacked substrate is heated to about 500° C. to react silicon with the metal film, thereby the silicide layer S1 is formed. Subsequently, a wet etching process is performed using a mixture of sulfuric acid and hydrogen peroxide to remove the metal film and a surplus silicide layer formed on each of the insulating film, the element isolation region EI, and the sidewall. Subsequently, heat treatment of about 800° C. is further performed to form the desired silicide layer S1 only on each of the surfaces of the diffusion regions and the gate electrodes. Some silicide layer S1 on the p-type diffusion region PD in the seal ring region 1B is formed so as to surround the circuit region 1A in plan view, and has an annular plan layout.

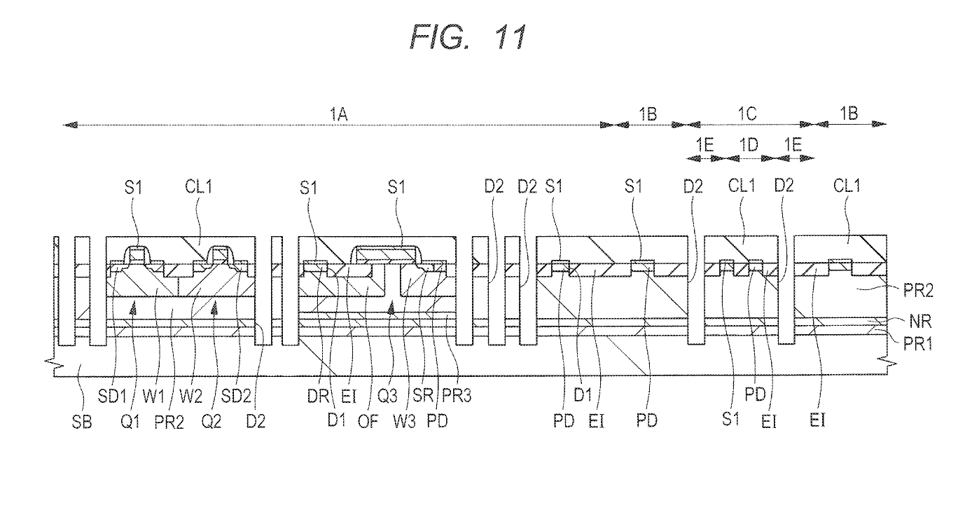

Subsequently, as shown in FIG. 11, an interlayer insulating film (contact interlayer film) CL1 including a silicon nitride film, a silicon oxide film made from tetra ethyl ortho silicate (TEOS), or a stacked film of such films is formed by a CVD process. Subsequently, planarization is performed by, for example, a chemical mechanical polishing (CMP) process to planarize the upper surface of the interlayer insulating film CL1. Subsequently, the interlayer insulating film CL1, the element isolation region EI, the epitaxial layer, and the semiconductor substrate SB are processed by a patterning step using a photolithography technique and a dry etching process to form a plurality of trenches D2. The trench D2 is formed not only in a portion where the DTI structure is formed later, but also in a portion where the substrate contact plug is formed later in the circuit region 1A. That is, the trenches D2 include a trench for DTI structure formation and a trench for substrate contact plug formation.

In this step, a plurality of trenches D2 are formed in the circuit region 1A, no trench D2 is formed in the seal ring region 1B, one annular trench D2 is formed in the peripheral region 1E so as to surround the circuit region 1A and the seal ring region 1B in plan view, and no trench D2 is formed in the cutting region 1D.

Each trench D2 is a deep recess that extends up to the intermediate depth of the semiconductor substrate SB through the interlayer insulating film CL1, the element isolation region EI, and the epitaxial layer. The trench D2 has a lateral width of 0.8 nm, for example. After formation of the trenches D2, a p-type semiconductor region may be formed by an ion implantation process or the like on the bottom of each trench D2 to increase an isolation withstand voltage.

Subsequently, as shown in FIG. 12, an insulating film (interlayer insulating film) including, for example, a silicon oxide film is further formed (deposited) on the interlayer insulating film CL1 by a CVD process or the like. The interlayer insulating film CL including the interlayer insulating film CL1 and the overlying insulating film is thus formed. Each trench D2 is covered by that insulating film through formation of the insulating film. Subsequently, the upper surface of the interlayer insulating film CL is planarized by a CMP process or the like. FIG. 12 integrally shows the interlayer insulating film CL1 and the overlying insulating film, and does not show a boundary therebetween.

Subsequently, a photolithography technique and a dry etching process are used to perform patterning to form a plurality of contact holes (coupling holes) CH penetrating the interlayer insulating film CL. In the deposition step of the insulating film, although the insulating film is deposited on the side surface and the bottom surface of the trench D2, the trench D2 is not completely filled with the insulating film, i.e., partially hollowed. That is, the gap G1 is formed within the trench D2 while the interlayer insulating film CL exists over the inside of the trench D2. The interlayer insulating film CL and the gap G1 in a trench D2 different from a trench D2, in which the substrate contact plug is formed in a later step, configure the DTI structure used for element isolation. The DTI structure, including the trench D2 in the peripheral region 1E and the interlayer insulating film CL and the gap G1 in the trench D2, is a pseudo isolation part that does not electrically isolate semiconductor elements from each other, and does not electrically couple the stacked substrate to an interconnection, i.e., the dummy isolation part DI1.

The respective contact holes CH expose, at their bottoms, the silicide layer S1 on each of the upper surfaces of the gate electrode of the p-type low-withstand-voltage transistor Q1, the gate electrode of the n-type low-withstand-voltage transistor Q2, the gate electrode of the n-type high-withstand-voltage transistor Q3, the source-drain region SD1, the source-drain region SD2, the source region SR, and the drain region DR. Each contact hole CH has, for example, a circular shape in plan view, and has an average diameter of 0.1 μm, for example. The contact hole CH is not formed in the scribe region 1C, but is formed only in the circuit region 1A and in the seal ring region 1B. The contact hole CH in the seal ring region 1B is formed so as to surround the circuit region 1A in plan view, and has an annular plan layout. The upper surface of the silicide layer S1 covering the upper surface of the p-type diffusion region PD is exposed at the bottom of the contact hole CH in the seal ring region 1B.

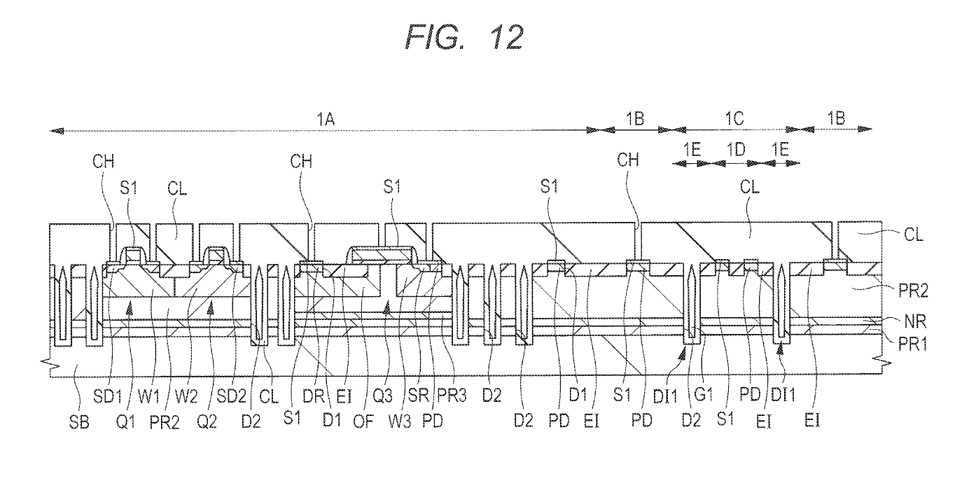

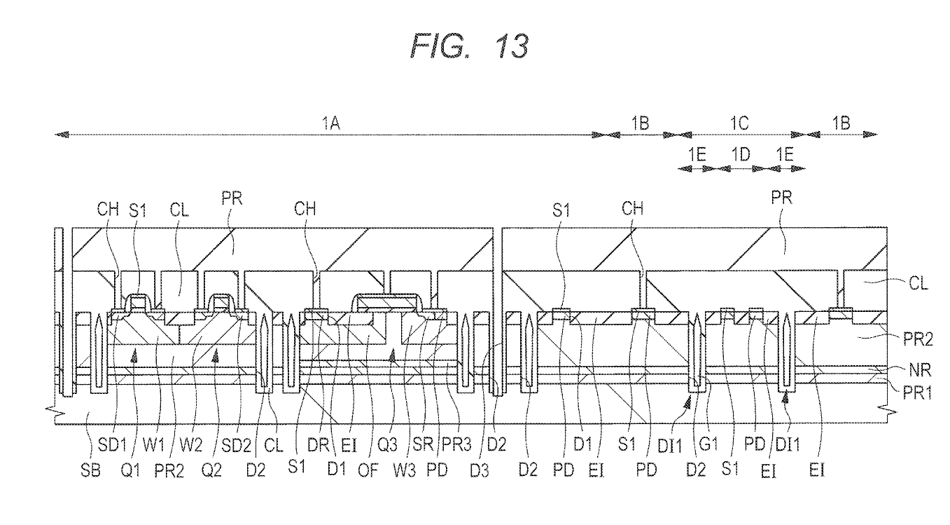

Subsequently, as shown in FIG. 13, a photolithography technique and a dry etching process are used to form the trenches (substrate contact trenches) D3 penetrating the interlayer insulating film CL. That is, first, a photoresist film PR as a resist pattern is formed on the interlayer insulating film CL including the insides of the contact holes CH. In other words, the photoresist film PR completely fills the insides of all the contact holes CH, and covers the upper surface of the interlayer insulating film CL. The photoresist film PR is a pattern exposing the upper surface of the interlayer insulating film CL directly over some of the trenches D2. Specifically, the photoresist film PR opens only portions in which the substrate contact trenches are formed, and the upper surface of the interlayer insulating film CL is exposed at the respective bottoms of such openings.

Subsequently, each trench D3 is formed by a dry etching process using the photoresist film PR as an etching mask so as to extend up to the intermediate depth of the semiconductor substrate SB below the bottom surface of the trench D2 through the interlayer insulating film CL, the element isolation region EI, and the epitaxial layer. The interlayer insulating film CL is gradually removed by etching from the upper surface to the lower side thereof, so that the trench D3 eventually reaches the gap G1 in the trench D2. As a result, the gap G1 in the trench D2 becomes part of the trench D3. Subsequently, the interlayer insulating film CL on the bottom of the trench D2 and the silicon oxide film and the silicon nitride film remaining on the bottom are removed by a dry etching process or the like, thereby the upper surface of the semiconductor substrate SB is exposed at the bottom of the trench D3. As a result, the trench D3 is formed so as to extend up to the semiconductor substrate SB from the upper surface of the interlayer insulating film CL. After the trench D3 is formed, a p-type impurity may be implanted into the bottom of the trench D3 to reduce a resistance.

The trench D3 is not formed in the seal ring region 1B and the scribe region 1C, but is formed only in the circuit region 1A. The trench D3 forms, for example, a pattern extending in a horizontal direction along the main surface of the semiconductor substrate SB, and has a width in a lateral direction of 0.5 μm, for example.

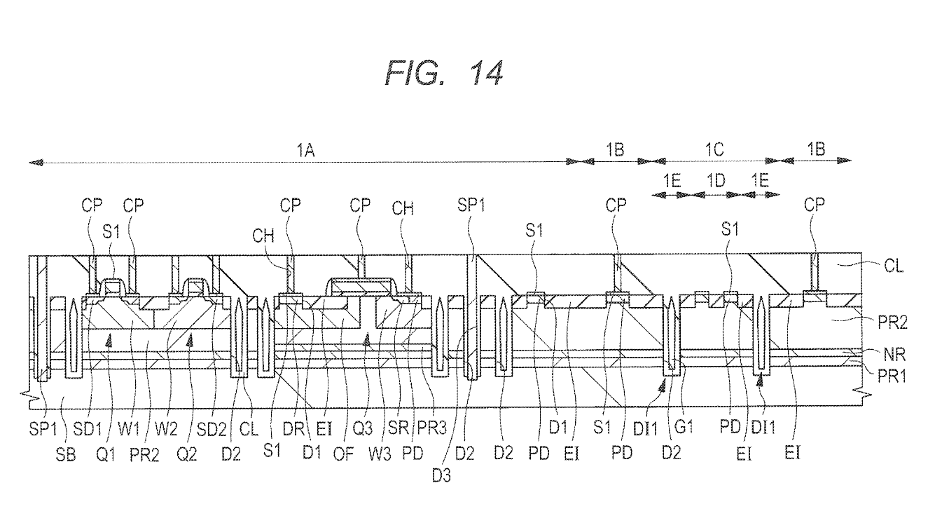

Subsequently, as shown in FIG. 14, the photoresist film PR is removed, and then the contact plug (conductive coupling part) CP is formed in each contact hole CH, and the substrate contact plug (conductive substrate coupling part) SP1 is formed in each trench D3. That is, a barrier metal film including, for example, a titanium (Ti) film, a titanium nitride (TiN) film, or a stacked film of such films is deposited over the entire main surface of the semiconductor substrate SB by a CVD process or a sputtering process. Subsequently, a film (main conductor film) mainly containing, for example, tungsten (W) is formed by a CVD process or the like to completely fill the contact hole CH and the trench D3. Subsequently, a surplus metal film on the interlayer insulating film CL is removed by a CMP process to expose the upper surface of the interlayer insulating film CL.

As a result, the contact plug CP including the barrier metal film and the main conductor film is formed in the contact hole CH, and the substrate contact plug SP1 including the barrier metal film and the main conductor film is formed in the trench D3. The substrate contact plug SP1 is a conductor film formed in the trench D3 in the circuit region 1A, and has a lower surface coupled to the semiconductor substrate SB and an upper surface planarized in substantially the same plane as the upper surface of the interlayer insulating film CL. The substrate contact plug SP1 is not formed in the seal ring region 1B, and the contact plug CP and the substrate contact plug SP1 are not formed in the scribe region 1C. The annular contact plug CP is formed in the seal ring region 1B so as to surround the circuit region 1A in plan view.

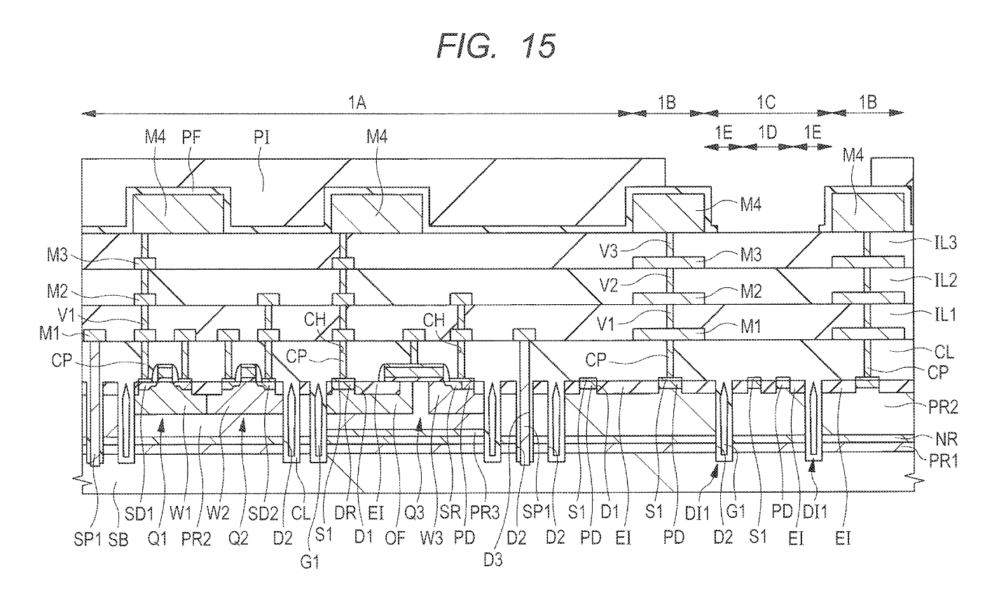

Subsequently, as shown in FIG. 15, a barrier metal film including, for example, titanium (Ti) film, a titanium nitride (TiN) film, or a stacked film of such films, and a main conductor film including an aluminum film are stacked on each of the interlayer insulating film CL, the contact plug CP, and the substrate contact plug SP1. Subsequently, a photolithography technique and an etching process are used to form a plurality of interconnections M1 each including the barrier metal film and the main conductor film. Part of the lower surface of each interconnection M1 is coupled to the upper surface of the contact plug CP or the substrate contact plug SP1. However, the interconnection M1 formed in the circuit region 1A is not coupled to the contact plug CP in the seal ring region 1B.

Subsequently, the interlayer insulating film IL1 including a silicon oxide film, a silicon nitride film, or a stacked film of such films is formed on the interlayer insulating film CL so as to cover the interconnection M1. Subsequently, the upper surface of the interlayer insulating film IL1 is planarized using a CMP process, for example.

Subsequently, the upper surface of the interconnection M1 is exposed using a photolithography technique and a dry etching process to form via holes penetrating the interlayer insulating film IL1. Subsequently, a barrier metal film including, for example, a titanium (Ti) film, a titanium nitride (TiN) film, or a stacked film of such films is deposited by a sputter process or the like, and then a film (main conductor film) mainly containing tungsten (W) is formed by a CVD process or the like to fill each via hole. Subsequently, the surplus barrier metal film and the surplus main conductor film on the interlayer insulating film IL1 are removed by a CMP process or the like, thereby the upper surface of the interlayer insulating film IL1 is exposed to form the via V1 including the barrier metal film and the main conductor film in the via hole. The first interconnection layer, including the interconnections M1, the interlayer insulating film IL1, and the vias V1, is thus formed.

Subsequently, the second interconnection layer and the third interconnection layer are formed in order over the first interconnection layer through steps similar to the step for the first interconnection layer. Subsequently, the interconnections M4 are formed on the third interconnection layer by a method similar to the formation method of the interconnections M1. The interconnections M1 to M4, the vias V1 to V3, and the contact plugs CP formed in the circuit region 1A are electrically coupled to the semiconductor element formed over the stacked substrate. The interconnection M1 to M4, the vias V1 to V3, and the contact plugs CP formed in the seal ring region 1B are electrically coupled to the p-type diffusion region PD in the upper surface of the semiconductor substrate SB via the contact plug CP and the silicide layer S1.

However, the interconnection M1 to M4, the vias V1 to V3, and the contact plugs CP formed in the circuit region 1A are not electrically coupled to the interconnection M1 to M4, the vias V1 to V3, the contact plugs CP, the silicide layer S1, and the p-type diffusion region PD formed in the seal ring region 1B. In other words, the seal ring including the interconnections M1 to M4, the vias V1 to V3, and the contact plugs CP formed in the seal ring region 1B, and the silicide layer S1 and the p-type diffusion region PD in the seal ring region 1B do not configure a circuit.

Subsequently, the passivation film PF covering the interconnection M4 and the polyimide film PI are formed in order, and then patterned to remove the passivation film PF and the polyimide film PI in the scribe region 1C. The upper surface of the interlayer insulating film IL3 in the scribe region 1C is thus exposed. The polyimide film PI in the cutting region 1D is particularly removed.

Subsequently, a dicing step is performed to singulate the semiconductor wafer WF (see FIG. 1). A region surrounded by a dashed line in FIG. 3, i.e., the cutting region 1D, extending in the scribe region 1C at the center between the chip regions CHR, is cut by a dicing blade. In the dicing step, a slit is formed from the upper side to the intermediate depth of the semiconductor wafer using a dicing blade having a relatively large cutting width, and then a substrate portion under the slit is cut using a dicing blade having a relatively small cutting width, so that the semiconductor wafer is cut.

As shown in FIGS. 16 and 17, a plurality of semiconductor chips CHP each including one chip region CHR (see FIG. 3) can be thus produced. The semiconductor device of the first embodiment is completed through the above-described steps. Two types of dicing blades having different cutting widths are used for dicing as described above. Hence, as shown in FIG. 17, a section of an end portion (side surface) of the semiconductor chip has differences in level.

In the dicing step, the dummy isolation part DI1 formed in the peripheral region 1E, and the seal ring including the interconnections M1 to M4, the vias V1 to V3, and the contact plugs CP formed in the seal ring region 1B prevent cracking and chipping due to breaking of the semiconductor wafer (semiconductor chip CHP). The seal ring further prevents infiltration of water into the circuit region 1A from a side surface side of the semiconductor chip CHP produced by the dicing step, and prevents the circuit region 1A from being contaminated with metal.

The interconnections, the vias, and the contact plugs CP configuring the seal ring are therefore formed annually along the periphery of the semiconductor chip CHP to protect the circuit region 1A by the seal ring. Similarly, the dummy isolation part DI1 is formed annually along the periphery of the semiconductor chip CHP to protect the circuit region 1A by the dummy isolation part DI1.

The interconnections M1 to M4, the vias V1 to V3, and the contact plugs CP in the seal ring region 1B are formed so as to overlap one another in a direction (vertical direction) as nearly perpendicular as possible to the main surface of the semiconductor substrate SB in order to protect the circuit region 1A by the seal ring.

### Effects of First Embodiment

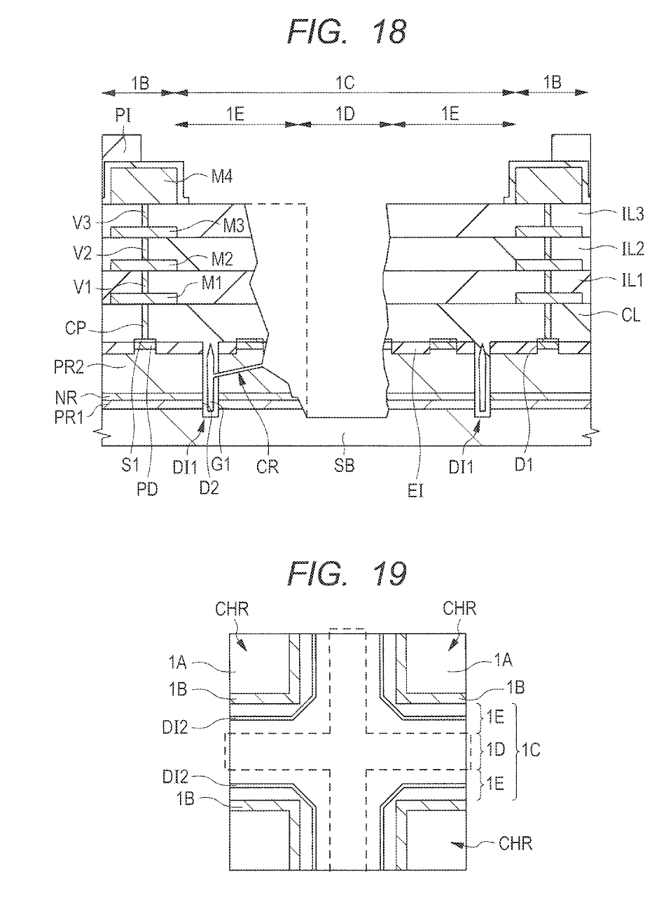

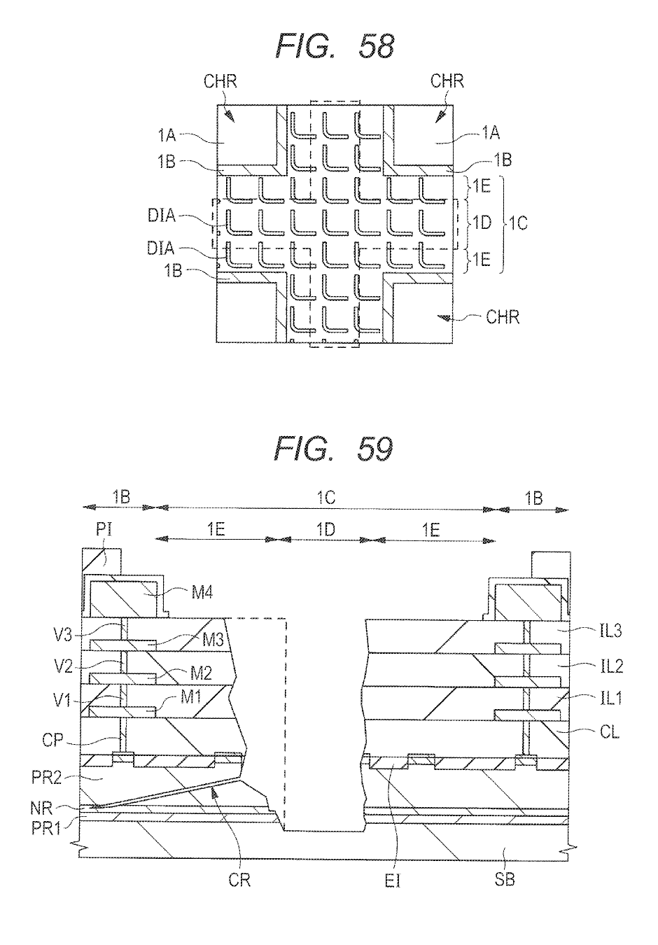

Effects of the first embodiment are described below with reference to FIGS. 58, 59, and 18. FIG. 58 is a plan view of a semiconductor device of a comparative example during a manufacturing process of the semiconductor device. FIG. 59 is a plan view of the semiconductor device of the comparative example during the manufacturing process. FIG. 59 corresponds to FIG. 5, showing the seal ring region 1B and the scribe region 1C. FIG. 58 shows a structure of the semiconductor wafer shown in FIG. 59 in the middle of cutting in the dicing step. FIG. 18 is a sectional view of the semiconductor device of the first embodiment during the manufacturing process of the semiconductor device, showing a portion corresponding to the portion shown in FIGS. 5 and 59. That is, FIG. 18 shows two seal ring regions 1B and the scribe region 1C therebetween. FIGS. 18 and 59 each show a section of the semiconductor wafer that has been slit by a dicing blade having a relatively large cutting width, but has still not been cut by a dicing blade having a relatively small cutting width.

As shown in FIG. 58, the semiconductor wafer of the comparative example has a plurality of dummy isolation parts DIA in each of the peripheral region 1E and the cutting region 1D. The comparative example is further different from the first embodiment in that the dummy isolation parts DIA in the peripheral region 1E do not have the annular structure surrounding the circuit region 1A and the seal ring region 1B. In the comparative example, a plurality of dummy isolation parts DIA, each having a width smaller than the width of the circuit region 1A in the first or second direction, are formed separately from one another in the scribe region 1C. A plurality of island-like dummy isolation parts DIA each having an L-shaped layout in plan view are arranged in a matrix. Other structures of the semiconductor device of the comparative example are similar to those of the semiconductor device of the first embodiment. FIG. 59 shows a section of a portion where no dummy isolation part DIA is formed in the scribe region 1C.

In a manufacturing process of a semiconductor device, a dummy pattern is preferably disposed for stabilization of pattern occupancy and improvement in uniformity of a surface to be polished in a polishing step in order to secure a high yield. In a manufacturing process of the semiconductor device using the DTI structure for element isolation or a substrate contact through-hole, a trench having a high aspect ratio is formed, and then an insulating film is deposited on the inside of the trench. Subsequently, planarization is performed by polishing using a CMP process, and a dummy pattern (dummy isolation part) including the DTI structure is preferably disposed in light of improving uniformity of the polished surface.

On the other hand, when the dummy isolation parts DIA as dummy patterns each including the DTI structure are disposed in the cutting region 1D as shown in FIG. 58, chipping or cracking may occur in the dicing step. This is because chipping or cracking occurs because of existence of the DTI structure in the cutting region 1D due to vibration or chipping during dicing. In FIG. 59, a region shown by a dashed line is broken, and chipping occurs in the region. However, such chipping occurs only in the scribe region 1C rather than in the seal ring region 1B; hence, the chipping does not directly reduce reliability of the semiconductor device.

However, as shown in FIG. 59, a crack CR occurs in the stacked substrate including the semiconductor substrate SB from a portion where the semiconductor wafer is broken by chipping. In this case, the crack CR extends from a cutting region 1D side toward the circuit region 1A through below the contact plug CP configuring the seal ring in the seal ring region 1B.

If the crack CR advances due to stress generated in a subsequent dicing step or a later package step, the crack CR eventually reaches the inside of the semiconductor chip. This may cause short-circuit between the element in the semiconductor chip and the semiconductor substrate SB, resulting in a trouble in operation of the semiconductor device. The chipping and cracking, which are caused by the dummy isolation parts DIA in the dicing step, easily occur in the case where the dummy isolation part DIA strides the boundary of a region along which the semiconductor chip is diced, i.e., the boundary between the cutting region 1D and the peripheral region 1E. Furthermore, the chipping and cracking, which are caused by the dummy isolation parts DIA in the dicing step, easily occur at a slit (terminal portion) and a bent portion of the dummy isolation part DIA.

On the other hand, in the first embodiment, as shown in FIGS. 2 and 3, the annular dummy isolation part DI1 is formed in the peripheral region 1E so as to surround the circuit region 1A and the seal ring region 1B. The cutting region 1D has no dummy isolation part DI1. That is, no DTI structure is formed in the cutting region 1D. As a result, the trench (for example, trench D2) deeper than the trench D1, the DTI structure, and the dummy isolation part are each not exposed on a side surface of the individual semiconductor chip formed by dicing. This makes it possible to avoid the dummy isolation part DI1 from striding the boundary of the region to be diced, and decrease the slits and the bent portions, which tend to cause chipping, of the dummy isolation part. It is therefore possible to prevent chipping and cracking during the dicing step due to existence of the dummy isolation part.

The dummy isolation part DI1, which is formed in the uncut peripheral region 1E so as to surround the chip region CHR, is disposed to be a wall on the periphery of the chip region CHR when the chip region CHR is viewed from the region to be diced (cutting region 1D). As shown in FIG. 18, this makes it possible to prevent the chipping or the crack CR occurring during dicing from advancing to a chip side (circuit region 1A side). That is, even after the semiconductor chip is completed through the dicing step, it is possible to prevent formation of the crack CR or chipping inside the dummy isolation part DI1, i.e., on the circuit region 1A side due to stress generated in a package step, or the like.

For example, as shown in FIG. 18, when the crack CR occurs from the cutting region 1D side to the circuit region 1A side, advancement of the crack CR in the stacked substrate cannot be prevented only by the seal ring on the stacked substrate as in the comparative example, but can be prevented by the dummy isolation part DI1 (in particular, the internal gap G1) in the first embodiment. The crack CR, which occurs on an outer side compared with the dummy isolation part DI1 with respect to the circuit region 1A, i.e., on a side close to the end of the semiconductor chip, is terminated at a portion overlapping the dummy isolation part DI1 in plan view. The cracking and chipping are thus prevented from advancing toward the center of the semiconductor chip, which makes it possible to prevent that the semiconductor device does not normally operated due the cracking or chipping in the circuit region 1A, leading to improvement in reliability of the semiconductor device.

The dummy isolation part DI1 is disposed on an outer side compared with the contact plug CP with respect to the circuit region 1A, i.e., on a side close to the end of the semiconductor chip CHP in the seal ring region 1B in light of preventing cracking or chipping initiated in the vicinity of the cutting region 1D from advancing to the circuit region 1A side.

### First Modification

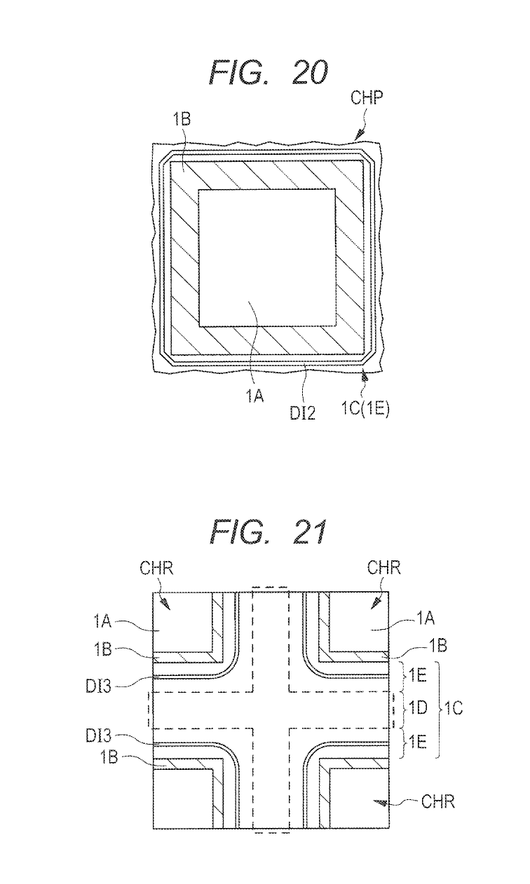

FIGS. 19 and 20 each show a plan view of a semiconductor device of a first modification of the first embodiment. FIG. 19 is a plan view corresponding to FIG. 3, showing the scribe region 1C before dicing. FIG. 20 is a plan view showing the semiconductor chip CHP after singulation by dicing.

Although FIGS. 3 and 6 show a layout where the dummy isolation part DI1 has a corner bent at 90° in plan view, as shown in FIGS. 19 and 20, a corner in plan view of a dummy isolation part DI2 surrounding the circuit region 1A and the seal ring region 1B may be configured by a portion extending in a direction inclined at 45° with respect to each of the first and second directions. Specifically, the dummy isolation part DI2 includes a first portion extending in the first direction along a first side of the chip region CHR having a rectangular plan layout, and a second portion extending in the second direction along a second side of the chip region CHR, and the dummy isolation part DI2 in a boundary portion (corner) that joins the first portion to the second portion has a layout extending in an oblique direction with respect to each side of the chip region CHR.

This makes it possible to provide effects similar to those of the semiconductor device described with reference to FIGS. 1 to 18. In addition, the dummy isolation part DI2 does not have the portion bent at 90°, which makes it possible to prevent cracking or chipping due to existence of the bent portion in plan view in the dummy isolation part DI2.

### Second Modification

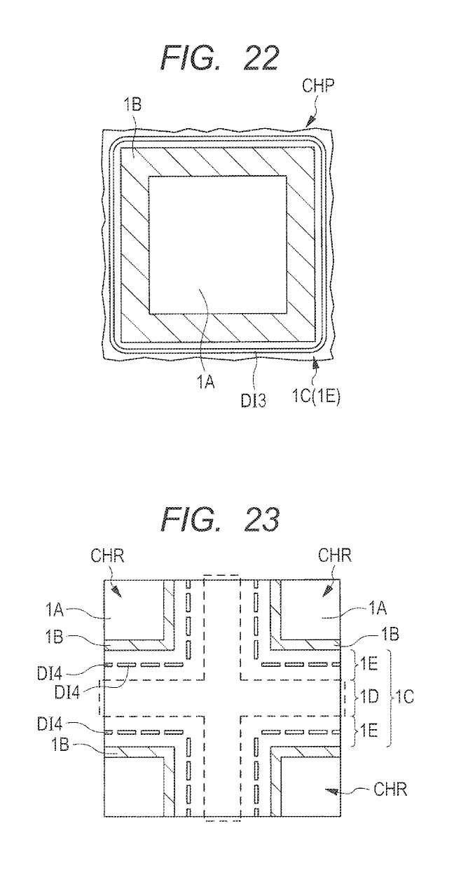

FIGS. 21 and 22 each show a plan view of a semiconductor device of a second modification of the first embodiment. FIG. 21 is a plan view corresponding to FIG. 3, showing the scribe region 1C before dicing. FIG. 22 is a plan view showing the semiconductor chip CHP after singulation by dicing.

Although FIGS. 3 and 6 show the layout where the dummy isolation part DI1 has the corner bent at 90° in plan view, a corner in plan view of a dummy isolation part D13 surrounding the circuit region 1A and the seal ring region 1B may be rounded as shown in FIGS. 21 and 22. Specifically, the dummy isolation part D13 of the second modification includes a first portion extending in the first direction along a first side of the chip region CHR having a rectangular plan layout, and a second portion extending in the second direction along a second side of the chip region CHR, and the dummy isolation part D13 in a boundary portion (corner) that joins the first portion to the second portion has a curvilinearly bent layout bent. In other words, in the second modification, the corner of the dummy isolation part D13 has a larger curvature radius than that in each of FIGS. 3 and 6.

In such a case, it is possible to provide effects similar to those of the semiconductor device described with reference to FIGS. 1 to 18. In addition, the dummy isolation part D13 does not have a portion bent at 90° and has the gradually bent corners, which makes it possible to prevent cracking or chipping due to existence of the bent portion in plan view in the dummy isolation part D13.

### Third Modification

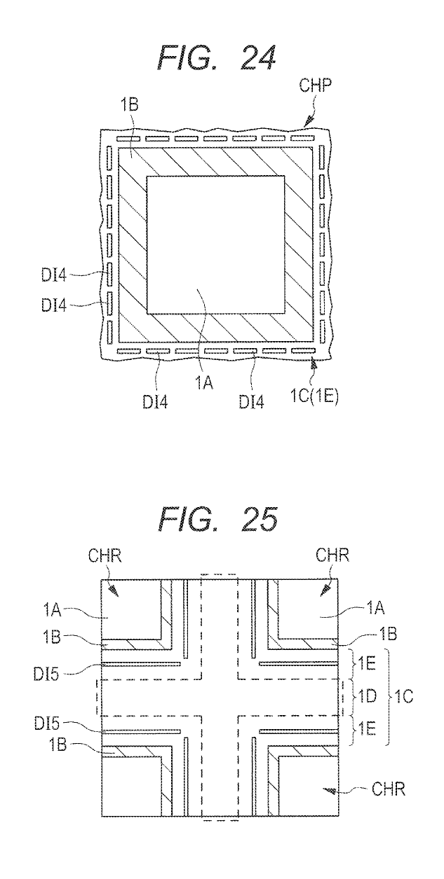

FIGS. 23 and 24 each show a plan view of a semiconductor device of a third modification of the first embodiment. FIG. 23 is a plan view corresponding to FIG. 3, showing the scribe region 1C before dicing. FIG. 24 is a plan view showing the semiconductor chip CHP after singulation by dicing.

As shown in FIGS. 23 and 24, a dummy isolation part DI4 around the circuit region 1A and the seal ring region 1B may have a dashed-line layout in plan view. Specifically, the dummy isolation part DI4 does not completely surround the circuit region 1A and the seal ring region 1B, i.e., the chip region CHR, and is configured by a plurality of linear patterns arranged intermittently. The dummy isolation part DI4 is also not formed in the cutting region 1D. Any of the arranged dummy isolation parts DI4 has a linear plan layout, and a dummy isolation part DI4 having a bent plan layout is not formed in the vicinity of the corner of the chip region CHR.

In such a case, no dummy isolation part is formed in the cutting region 1D, which makes it possible to prevent cracking or chipping in a dicing step due to existence of the dummy isolation part in the cutting region 1D. Since the dummy isolation part DI4 does not have a plan layout that is bent in the area around the corner of the chip region CHR, it is possible to prevent cracking or chipping due to existence of the bent portion in the dummy isolation part DI4. The dummy isolation part DI4 has the dashed-line layout. It is therefore easy to adjust occupancy in plan view of the dummy isolation part DI4 to prevent a reduction in flatness of a polished surface in a polishing step due to an excessively large amount of dummy isolation part DI4 in the peripheral region 1E in the seal ring region 1B.

### Fourth Modification

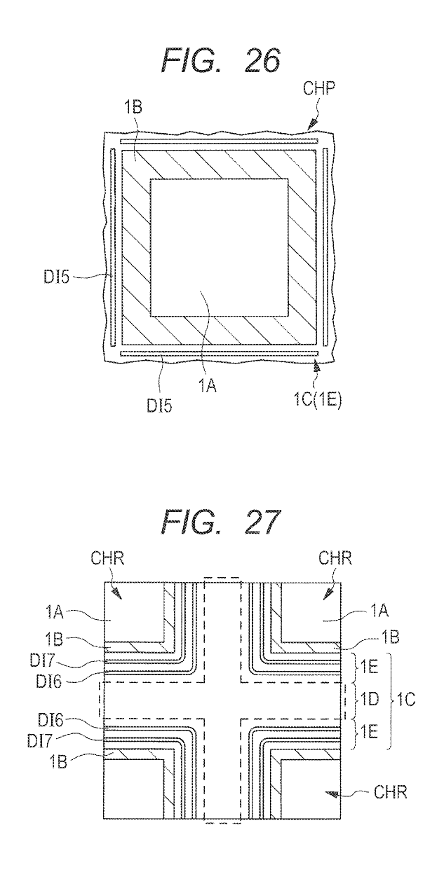

FIGS. 25 and 26 each show a plan view of a semiconductor device of a fourth modification of the first embodiment. FIG. 25 is a plan view corresponding to FIG. 3, showing the scribe region 1C before dicing. FIG. 26 is a plan view showing the semiconductor chip CHP after singulation by dicing.

As shown in FIGS. 25 and 26, a dummy isolation part DI5 surrounding the circuit region 1A and the seal ring region 1B includes no corner while including two first portions extending in the first direction along a first side of the chip region CHR having a rectangular plan layout, and two second portions extending in the second direction along a second side of the chip region CHR. Specifically, the dummy isolation part DI5 of the second modification does not completely surround the circuit region 1A and the seal ring region 1B, i.e., the chip region CHR, and is configured by four linear patterns along the respective four sides of the chip region CHR, and has no portion connecting the first portion to the second portion. The dummy isolation part DI5 is also not formed in the cutting region 1D. Any of the dummy isolation parts DI5 has a linear plan layout, and a dummy isolation part DI5 having a bent plan layout is not formed.

In such a case, no dummy isolation part is formed in the cutting region 1D, which makes it possible to prevent cracking or chipping in a dicing step due to existence of the dummy isolation part in the cutting region 1D. Since the dummy isolation part DI5 does not have a plan layout that is bent in the area around the corner of the chip region CHR, it is possible to prevent cracking or chipping due to existence of the bent portion in the dummy isolation part DI5.

### Fifth Modification

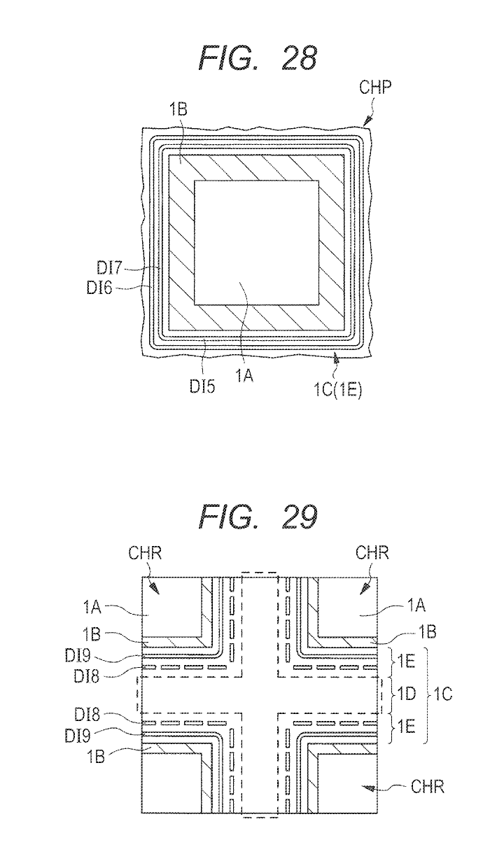

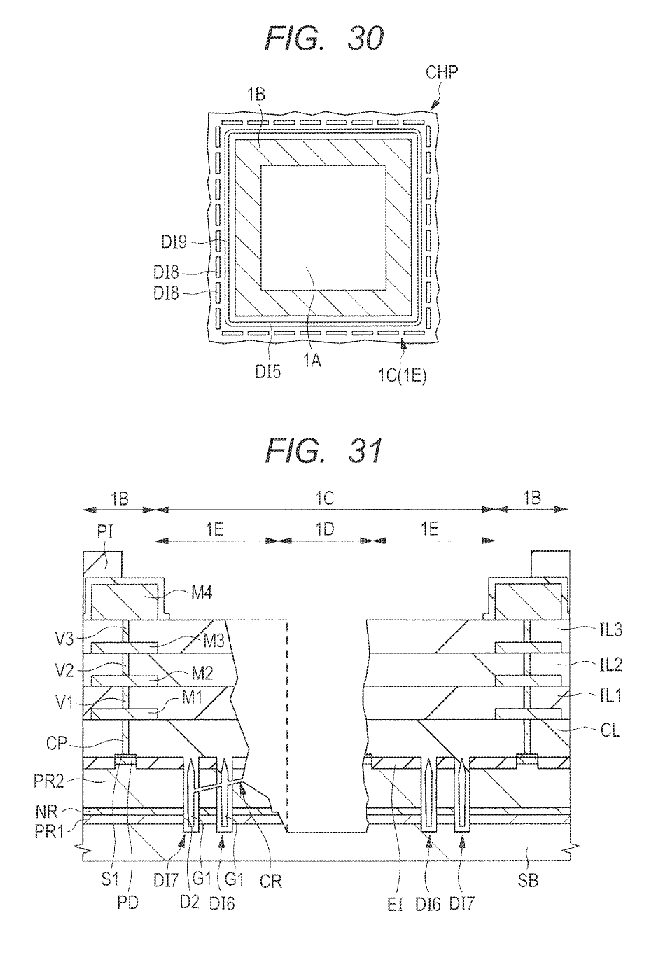

FIGS. 27 to 30 each show a plan view of a semiconductor device of a fifth modification of the first embodiment. FIG. 31 shows a sectional view of the semiconductor device of the fifth modification of the first embodiment. FIGS. 27 and 29 are each a plan view corresponding to FIG. 3, showing the scribe region 1C before dicing. FIGS. 28 and 30 are each a plan view showing the semiconductor chip CHP after singulation by dicing. FIG. 31 shows a sectional view corresponding to FIG. 18, showing the semiconductor device during a dicing step.

As shown in FIGS. 27 to 31, dummy isolation parts D16 and DI7 may doubly surround the circuit region 1A and the seal ring region 1B. Specifically, as shown in FIGS. 27 and 28, the semiconductor chip may have the annular dummy isolation part D16 surrounding the chip region CHR, and the dummy isolation part DI7 provided between the dummy isolation part D16 and the seal ring region 1B. The dummy isolation parts D16 and D17 have the same structure. The outer dummy isolation part of the double dummy isolation parts may have a dashed-line plan layout as in the third modification. Specifically, as shown in FIGS. 29 and 30, the semiconductor chip may have a dashed-line dummy isolation part D18 surrounding the chip region CHR, and a dummy isolation part D19 provided between the dummy isolation part D18 and the seal ring region 1B.

In such a case, the semiconductor device includes at least one annular dummy isolation part surrounding the chip region in plan view, and thus can provide effects similar to those of the semiconductor device described with reference to FIGS. 1 to 18. In addition, another dummy isolation part is further provided outside such an annular dummy isolation part, making it possible to improve reliability of the semiconductor device. For example, during dicing of the semiconductor wafer shown in FIG. 27, if a crack CR occurs due to chipping as shown in FIG. 31, and even if the outer dummy isolation part D16 cannot prevent advancement of the crack CR, the inner dummy isolation part DI7 can prevent advancement of the crack CR. It is therefore possible to more notably provide the effect of preventing the cracking or chipping from advancing toward the circuit region 1A.

The number of the dummy isolation parts can be increased, making it easy to adjust the area occupancy in plan view of the dummy isolation parts to improve flatness of a polished surface in a polishing step.

### Second Embodiment

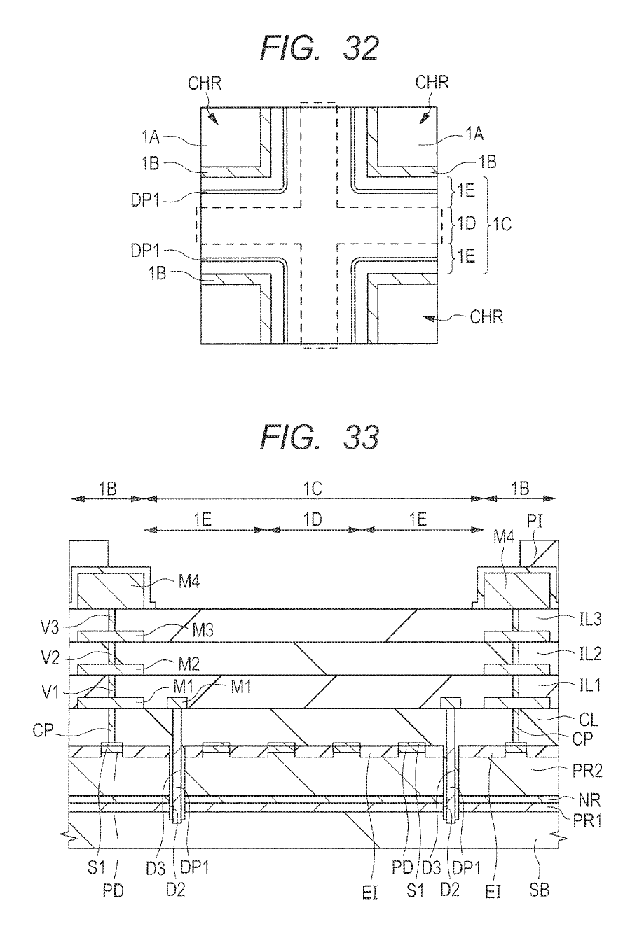

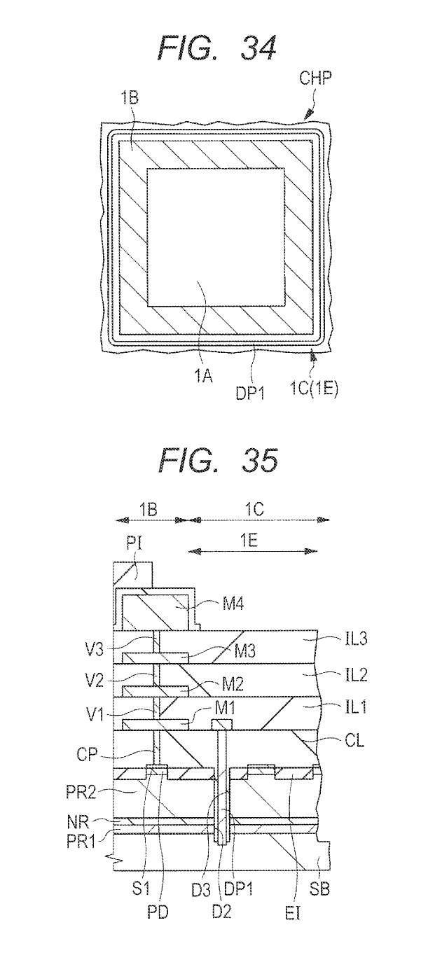

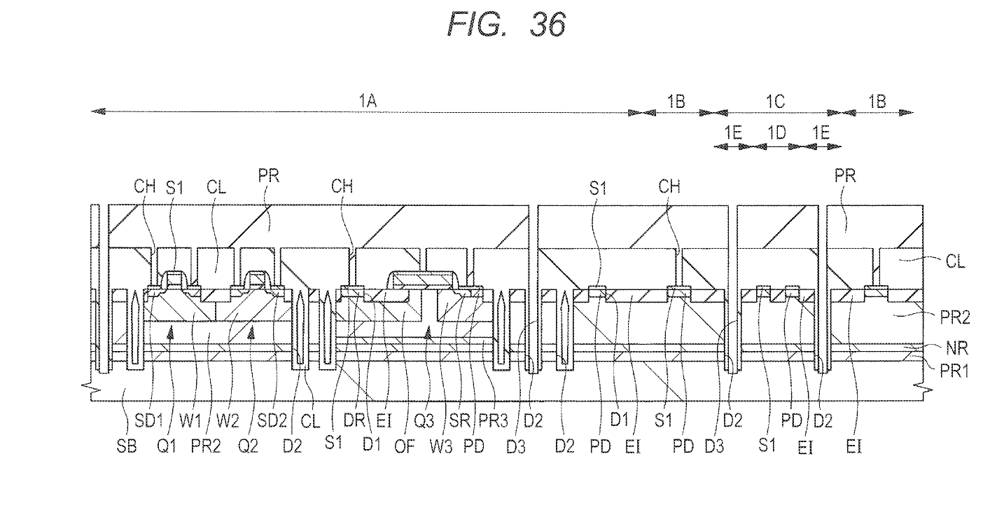

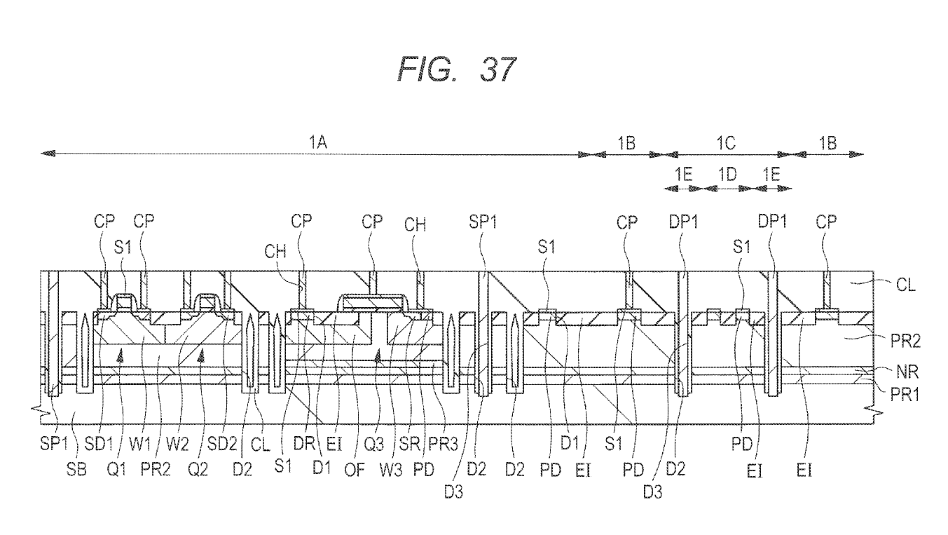

A dummy substrate contact plug is formed so as to penetrate the DTI structure formed in the peripheral region of the scribe region. Such formation of the dummy substrate contact plug is described below with reference to FIGS. 32 to 37. FIGS. 32 and 34 are each a plan view of a semiconductor device of a second embodiment. FIGS. 33 and 35 are each a sectional view of the semiconductor device of the second embodiment. FIGS. 36 and 37 are each a sectional view of the semiconductor device of the second embodiment during a manufacturing process of the semiconductor device. The semiconductor device of FIGS. 32 and 33 corresponds to part of the semiconductor wafer before a dicing step, and FIGS. 34 and 35 show the semiconductor chip after the dicing step. FIG. 33 shows the seal ring region 1B and the scribe region 1C.

The structure of the semiconductor device of the second embodiment is different from that of the first embodiment in that dummy substrate contact plugs DP1 shown in FIGS. 32 to 35 are formed in place of the dummy isolation parts DI1 in the first embodiment described with reference to FIGS. 3 and 6. Specifically, as shown in FIGS. 32 and 33, each dummy substrate contact plug DP1 is formed within the trench D2 formed in the peripheral region 1E while the interlayer insulating film CL exists over the inside of the trench D2, and extends from the upper surface of the interlayer insulating film CL to the intermediate depth of the stacked substrate below the bottom surface of the trench D2. The upper surface of the dummy substrate contact plugs DP1 is coupled to the bottom surface of the interconnection M1 formed on the interlayer insulating film CL and covered with the interlayer insulating film IL1.

That is, the dummy substrate contact plug DP1 has the same structure as the substrate contact plug SP1. However, the dummy substrate contact plug DP1 has an annular layout surrounding the chip region CHR (the circuit region 1A and the seal ring region 1B) in plan view. The dummy isolation part including the DTI structure and the dummy substrate contact plug are each not formed in the cutting region 1D.

The semiconductor chip CHP shown in FIGS. 34 and 35 can be given through cutting of such a semiconductor wafer. The dummy substrate contact plug DP1 is a pseudo substrate contact plug (conductive substrate coupling part) that does not configure a circuit and thus does not receive a voltage.

When the semiconductor device of the second embodiment is manufactured, steps described with reference to FIGS. 8 to 12 are performed, and then, as shown in FIG. 36, the trench D3 penetrating the trench D2 is formed in the peripheral region 1E in addition to the circuit region 1A. The trench D3 penetrating the trench D2 surrounding the circuit region 1A and the seal ring region 1B in plan view is formed annually so as to surround the circuit region 1A and the seal ring region 1B in plan view.

Subsequently, as shown in FIG. 37, the step described with reference to FIG. 14 is performed to form the dummy substrate contact plugs DP1 in the peripheral region 1E together with the substrate contact plug SP1. Subsequently, steps similar to the steps described with reference to FIGS. 15 to 17 are performed, thereby the semiconductor device of the second embodiment shown in FIGS. 34 and 35 is completed.

In the second embodiment, unlike the first embodiment, the dummy substrate contact plugs DP1 is formed instead of the gap within the DTI structure in the peripheral region 1E shown in FIG. 35. When cracking or chipping occurs from a cutting region 1D side to a circuit region 1A side during or after the dicing step, the substrate contact plug made of, for example, metal has a higher ability of preventing such cracking or chipping than the gap. Hence, the second embodiment, in which the dummy substrate contact plugs DP1 is provided in the peripheral region 1E, can more effectively prevent advancement of the cracking and chipping than the first embodiment. It is therefore possible to improve reliability of the semiconductor device.

### Third Embodiment

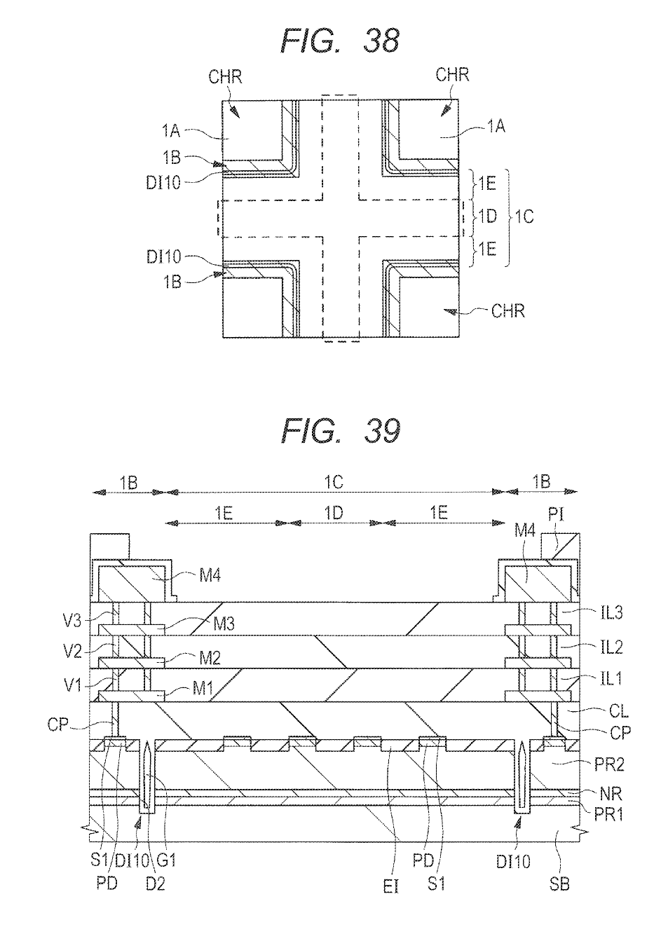

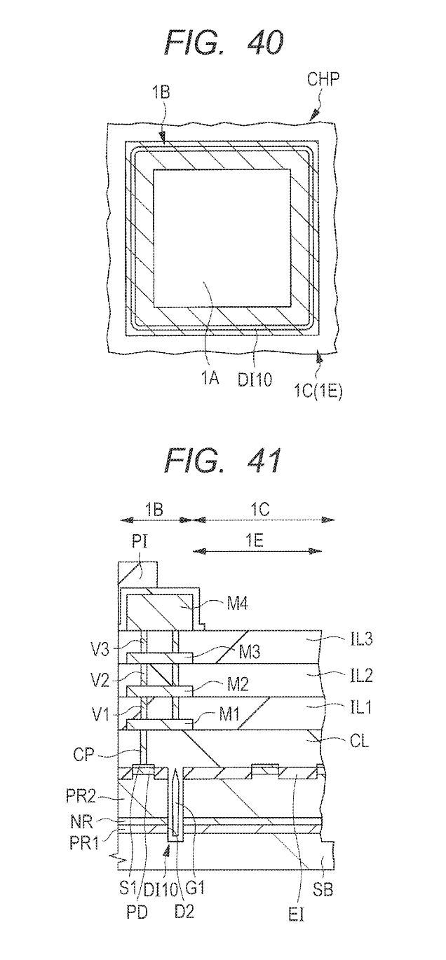

Formation of a dummy isolation part in the seal ring region is described below with reference to FIGS. 38 to 41. FIGS. 38 and 40 are each a plan view of a semiconductor device of a third embodiment. FIGS. 39 and 41 are each a sectional view of the semiconductor device of the third embodiment. The semiconductor device of FIGS. 38 and 39 corresponds to part of the semiconductor wafer before a dicing step, and FIGS. 40 and 41 show the semiconductor chip after the dicing step. FIG. 39 shows the seal ring region 1B and the scribe region 1C.

As shown in FIGS. 38 and 39, a dummy isolation part DI10 is formed in the seal ring region 1B. Specifically, the dummy isolation part DI10 has the DTI structure, and includes the trench D2 extending from the upper surface of the element isolation region EI to the intermediate depth of the stacked substrate, and the gap G1 formed within the trench D2 while the interlayer insulating film CL exists over the inside of the trench D2. The dummy isolation part DI10 is formed directly below the interconnections M1 to M4 configuring the seal ring in the seal ring region 1B, and is formed annually so as to surround the circuit region 1A in plan view. The contact plug CP coupled to the lower surface of the interconnection M1 is located closer to the circuit region 1A than the dummy isolation part DUO, and is formed so as to surround the circuit region 1A in plan view, and is coupled to the p-type diffusion region PD via the silicide layer S1.

Although only one contact plug CP configuring the seal ring is formed, the respective vias V1 to V3 are formed doubly in the interconnections above the interconnection M1 so as to surround the circuit region 1A. That is, for example, a first annular via V1 surrounding the circuit region 1A and a second via V1 surrounding the first via V1 are formed directly over the interconnection M1. Such a structure is also formed in the semiconductor chip after the dicing step as shown in FIGS. 40 and 41.

As described above, the respective vias V1 to V3 are formed doubly in the seal ring region 1B, and only one contact plug CP is provided. This is because mechanical strength of each of the interlayer insulating films IL1 to IL3 is lower than that of the interlayer insulating film CL. That is, the seal ring is provided to prevent entering of water or metal from the outside of the semiconductor chip. While the interlayer insulating film CL, in which the contact hole CH is formed, is formed of a silicon oxide film, a silicon nitride film, or a stacked film of such films, the interlayer insulating films IL1 to IL3, in which the via holes are formed, may be made of a material having a smaller dielectric constant than the silicon oxide film to reduce a delay in each interconnection layer. Each of the interlayer insulating films IL1 to IL3 having the via holes therefore has a lower mechanical strength than the interlayer insulating film CL.

Hence, many vias V1 to V3 may each be necessary to be arranged side by side compared with the contact plug CP formed in the seal ring region 1B. In the third embodiment, while the double vias are formed for each interconnection layer, only one contact plug CP is formed. As a result, a blank region having no contact plug, no silicide layer S1, and no p-type diffusion region PD exists alongside the contact plug CP directly below the interconnection M1 configuring the seal ring. The dummy isolation part DI10 is therefore disposed in that brank region, and thus can be effectively disposed compared with the first embodiment. In other words, even if the dummy isolation part is not provided in the scribe region 1C, effects similar to those of the first embodiment can be exhibited, and consequently the peripheral region 1E can be reduced.

The dummy isolation part DI10 is disposed on an outer side compared with the contact plug CP with respect to the circuit region 1A in the seal ring region 1B, i.e., on a side close to the end of the semiconductor chip CHP in light of preventing the cracking and chipping initiated in the vicinity of the cutting region 1D from advancing toward the circuit region 1A. That is, the dummy isolation part DI10 is disposed closer to the scribe region 1C than the contact plug CP in the seal ring region 1B. This makes it possible to more effectively prevent advancement of the cracking and chipping compared with the case where the dummy isolation part DI10 is disposed on an inner side compared with the contact plug CP.

### First Modification

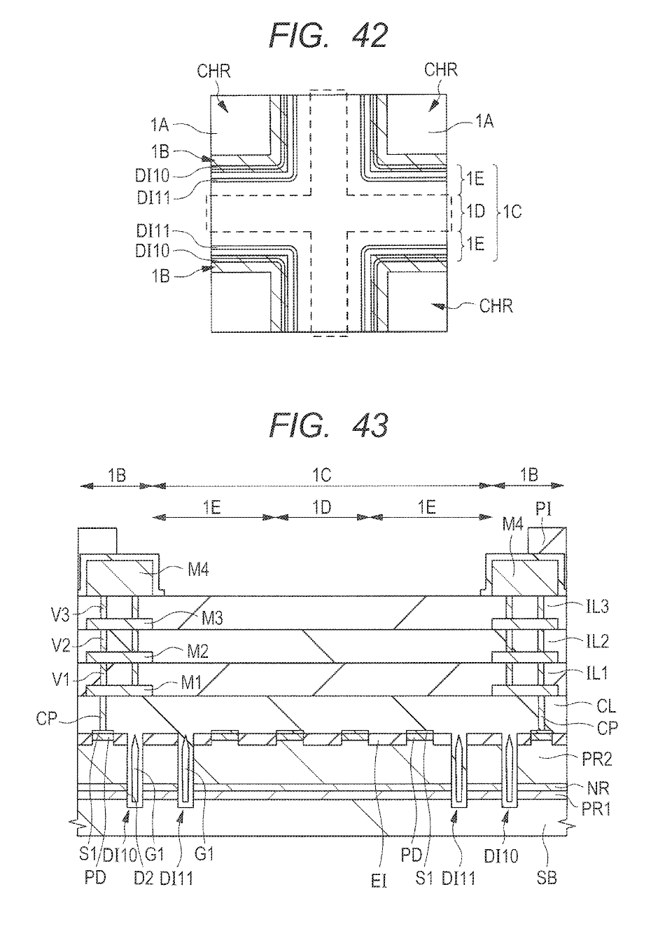

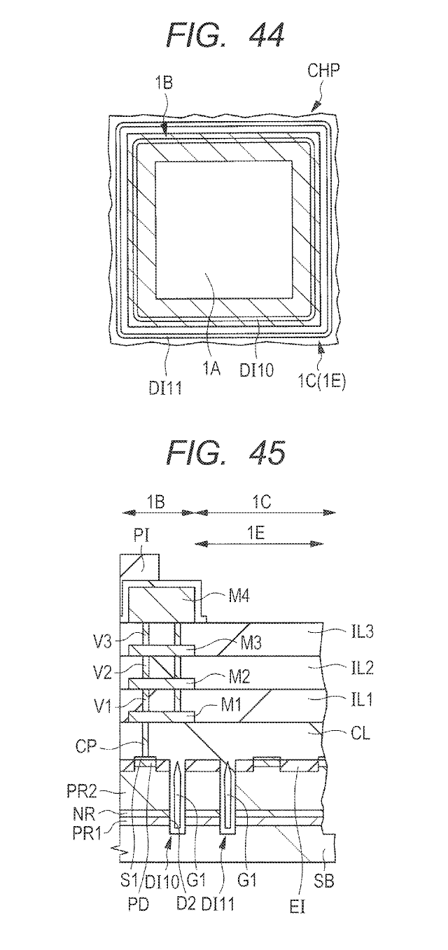

A semiconductor device of a first modification of the third embodiment is described with reference to FIGS. 42 to 45. FIGS. 42 and 44 are each a plan view of the semiconductor device of the first modification. FIGS. 43 and 45 are each a sectional view of the semiconductor device of the first modification. The semiconductor device of FIGS. 42 and 43 corresponds to part of a semiconductor wafer before a dicing step. FIGS. 44 and 45 show a semiconductor chip after the dicing step.

In the first modification, as shown in FIGS. 42 to 45, a dummy isolation part DI11 in the peripheral region 1E is formed in addition to the dummy isolation part DI10 in the seal ring region 1B. As described above, the double DTI structures are formed so as to surround the circuit region 1A, making it possible to more effectively prevent advancement of the cracking and chipping.

### Second Modification

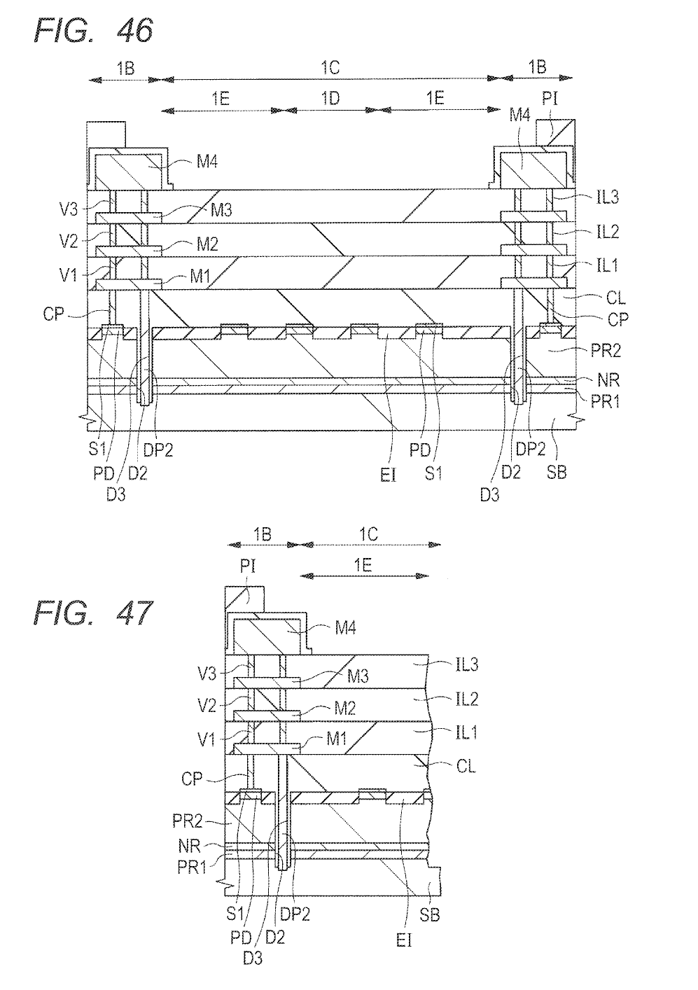

A semiconductor device of a second modification of the third embodiment is described with reference to FIGS. 46 to 47. FIGS. 46 and 47 are each a sectional view of the semiconductor device of the second modification. The semiconductor device of FIG. 46 corresponds to part of a semiconductor wafer before a dicing step. FIG. 47 shows an end portion of a semiconductor chip after the dicing step.

The semiconductor device of the second modification is different from the semiconductor device described with reference to FIGS. 38 to 41 in that a dummy substrate contact plug DP2 as shown in FIGS. 46 and 47 is formed in place of the dummy isolation part DI10 described with reference to FIGS. 38 to 41. Specifically, as shown in FIGS. 46 and 47, the dummy substrate contact plug DP2, which extends from the lower surface of the interconnection M1 to the intermediate depth of the stacked substrate, is disposed alongside of the contact plug CP configuring the seal ring directly below the interconnection M1 configuring the seal ring. The dummy substrate contact plug DP2 has a structure similar to that of the substrate contact plug SP1, and has an upper surface coupled to the bottom surface of the interconnection M1 covered with the interlayer insulating film IL1.

The dummy substrate contact plug DP2 surrounds the outer side of the contact plug CP having an annular plan layout, and has an annular layout surrounding the chip region CHR (the circuit region 1A and the seal ring region 1B) in plan view. The cutting region 1D has no dummy isolation part including the DTI structure and no dummy substrate contact plug. The dummy substrate contact plug DP2 is a pseudo substrate contact plug (conductive substrate coupling part) that does not configure a circuit and thus does not receive a voltage.

As described in the second embodiment, when cracking or chipping occurs from a cutting region 1D side to a circuit region 1A side, the substrate contact plug made of, for example, metal has a higher ability of preventing such cracking or chipping than the gap. Hence, the second modification having the dummy substrate contact plug DP2 in each of the trenches D2 and D3 in the seal ring region 1B can more effectively prevent advancement of the cracking and chipping than the semiconductor device described with reference to FIGS. 38 to 41. It is therefore possible to improve reliability of the semiconductor device.

The dummy substrate contact plug DP2 is disposed closer to the scribe region 1C than the contact plug CP in the seal ring region 1B. This makes it possible to more effectively prevent advancement of the cracking and chipping compared with the case where the dummy substrate contact plug DP2 is disposed on an inner side compared with the contact plug CP.

### Third Modification

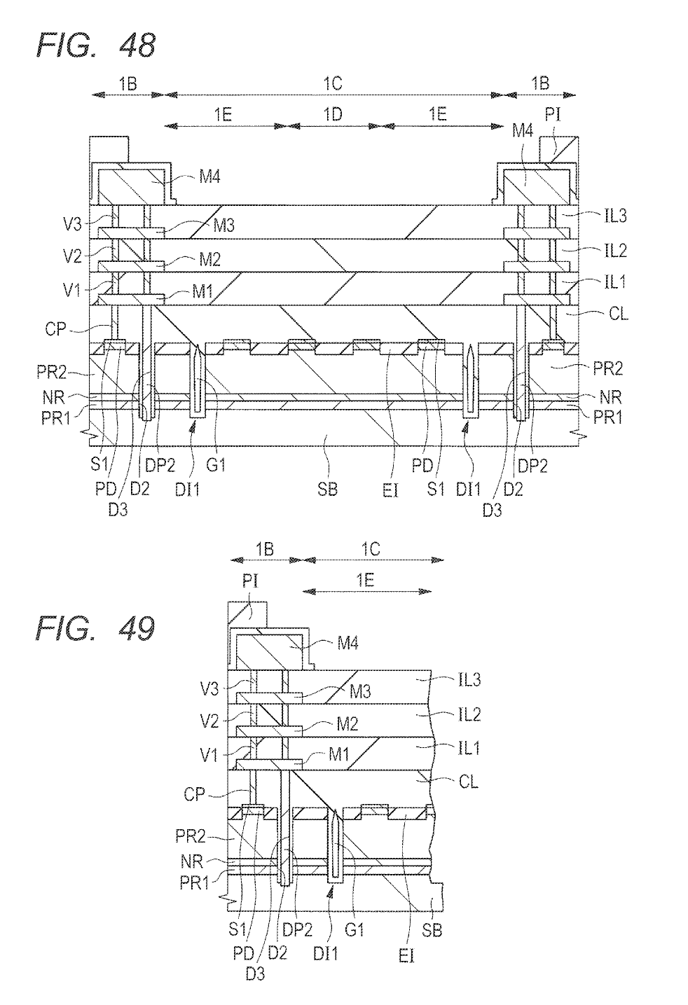

A semiconductor device of a third modification of the third embodiment is described with reference to FIGS. 48 and 49. FIGS. 48 and 49 are each a sectional view of the semiconductor device of the third modification. The semiconductor device of FIG. 48 corresponds to part of a semiconductor wafer before a dicing step. FIG. 49 shows an end portion of a semiconductor chip after the dicing step.

As shown in FIGS. 48 and 49, the second modification of the third embodiment may be combined with the first embodiment. Specifically, the annular dummy substrate contact plug DP2 surrounding the circuit region 1A may be provided in a region adjacent to the contact plug CP in the seal ring region 1B while the annular dummy isolation part DI1 surrounding the circuit region 1A and the seal ring region 1B is further formed in the peripheral region 1E.

The dummy isolation part DI1 and the dummy substrate contact plug DP2 are thus disposed together, which makes it possible to more effectively prevent advancement of the cracking and chipping compared with the second modification of the third embodiment and with the first embodiment.

### Fourth Modification

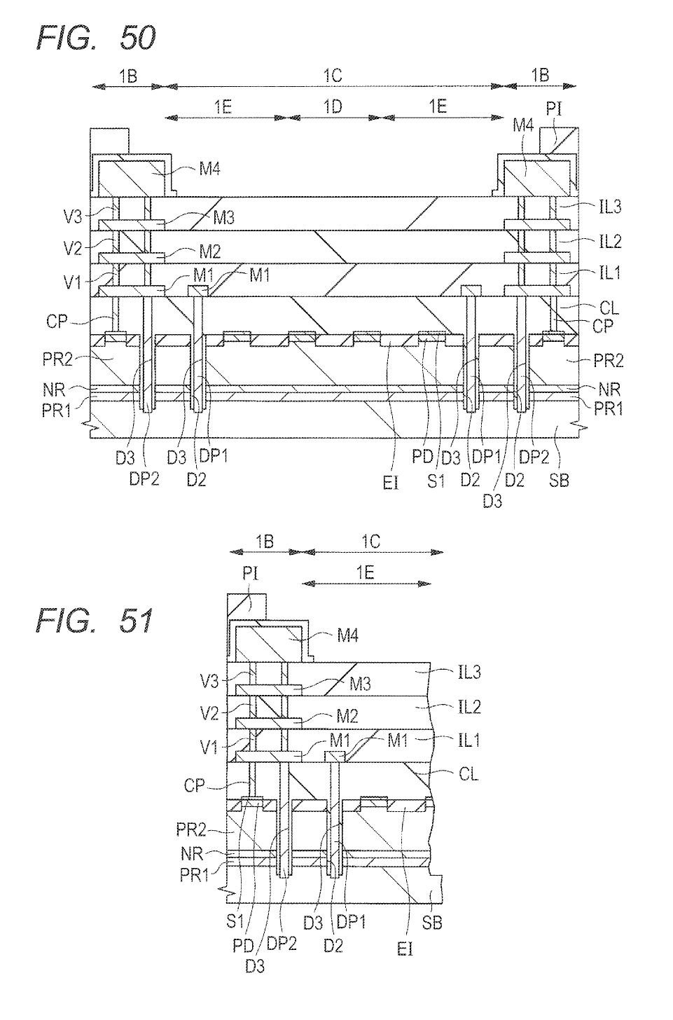

A semiconductor device of a fourth modification of the third embodiment is described with reference to FIGS. 50 and 51. FIGS. 50 and 51 are each a sectional view of the semiconductor device of the fourth modification. The semiconductor device of FIG. 50 corresponds to part of a semiconductor wafer before a dicing step. FIG. 51 shows an end portion of a semiconductor chip after the dicing step.

As shown in FIGS. 50 and 51, the second modification of the third embodiment may be combined with the second embodiment. Specifically, the annular dummy substrate contact plug DP2 surrounding the circuit region 1A may be provided in a region adjacent to the contact plug CP in the seal ring region 1B while the annular dummy substrate contact plug DP1 surrounding the circuit region 1A and the seal ring region 1B is formed in the peripheral region 1E.

The dummy substrate contact plugs DP1 and DP2 are thus disposed together, which makes it possible to more effectively prevent advancement of the cracking and chipping compared with the second modification of the third embodiment and with the second embodiment.

### Fifth Modification

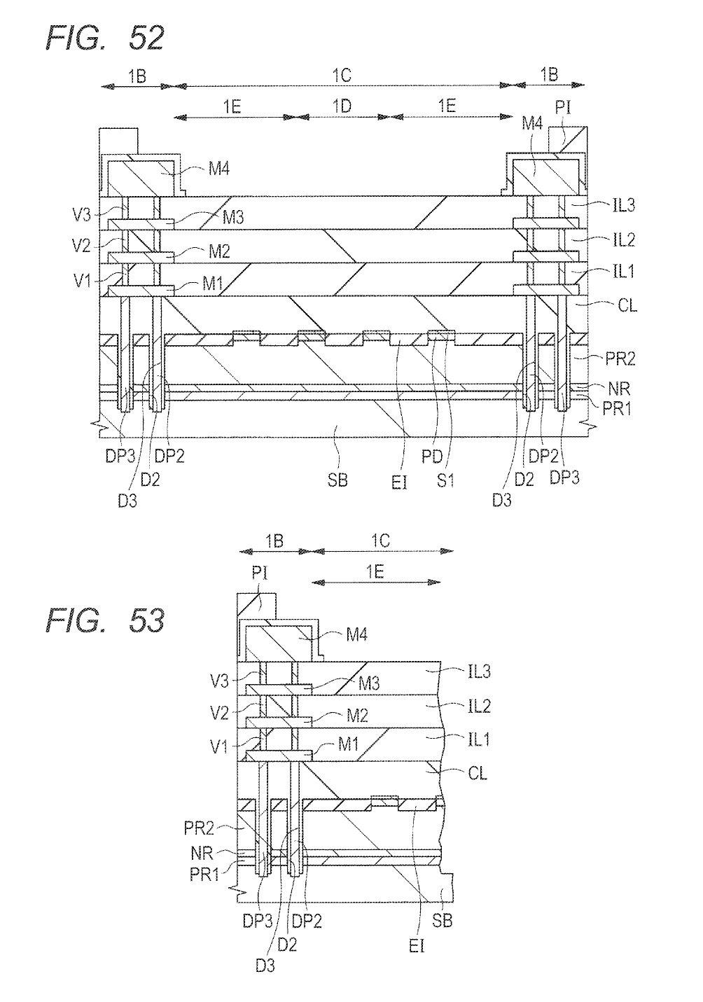

A semiconductor device of a fifth modification of the third embodiment is described with reference to FIGS. 52 and 53. FIGS. 52 and 53 are each a sectional view of the semiconductor device of the fifth modification. The semiconductor device of FIG. 52 corresponds to part of a semiconductor wafer before a dicing step. FIG. 53 shows an end portion of a semiconductor chip after the dicing step.

As shown in FIGS. 52 and 53, the semiconductor device of the fifth modification is different from that of the second modification of the third embodiment in that a dummy substrate contact plug DP3 is formed in addition to the dummy substrate contact plug DP2 on the lower surface of the interconnection M1 configuring the seal ring formed in the seal ring region 1B. That is, the dummy substrate contact plugs DP2 and DP3 having similar structures are arranged side by side directly below the interconnection M1. The dummy substrate contact plug DP3 is formed in a region between the dummy substrate contact plug DP2 surrounding the circuit region 1A and the circuit region 1A. While not shown, an annular contact plug CP (see FIG. 46) surrounding the circuit region 1A may be further coupled to the lower surface of the interconnection M1 in the seal ring region 1B.

The dummy substrate contact plugs DP2 and DP3 are arranged side by side directly below the interconnection M1 in the seal ring region 1B as in the fifth modification, making it possible to more effectively prevent advancement of the cracking and chipping compared with the second modification of the third embodiment.

### Sixth Modification

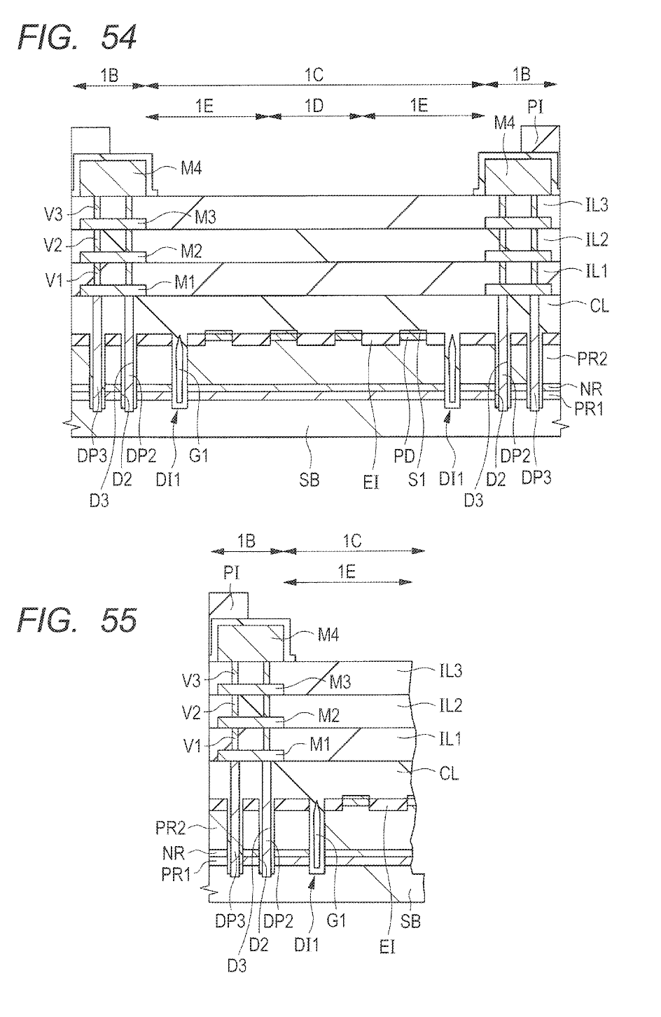

A semiconductor device of a sixth modification of the third embodiment is described with reference to FIGS. 54 and 55. FIGS. 54 and 55 are each a sectional view of the semiconductor device of the sixth modification. The semiconductor device of FIG. 54 corresponds to part of a semiconductor wafer before a dicing step. FIG. 55 shows an end portion of a semiconductor chip after the dicing step.

As shown in FIGS. 54 and 55, the fifth modification of the third embodiment may be combined with the first embodiment. Specifically, the dummy substrate contact plugs DP2 and DP3 may be provided directly below the interconnection M1 in the seal ring region 1B while the annular dummy isolation part DI1 surrounding the circuit region 1A and the seal ring region 1B is further formed in the peripheral region 1E.

The dummy isolation part DI1 and the dummy substrate contact plugs DP2 and DP3 are thus disposed together, which makes it possible to more effectively prevent advancement of the cracking and chipping compared with the fifth modification of the third embodiment and with the first embodiment.

### Seventh Modification

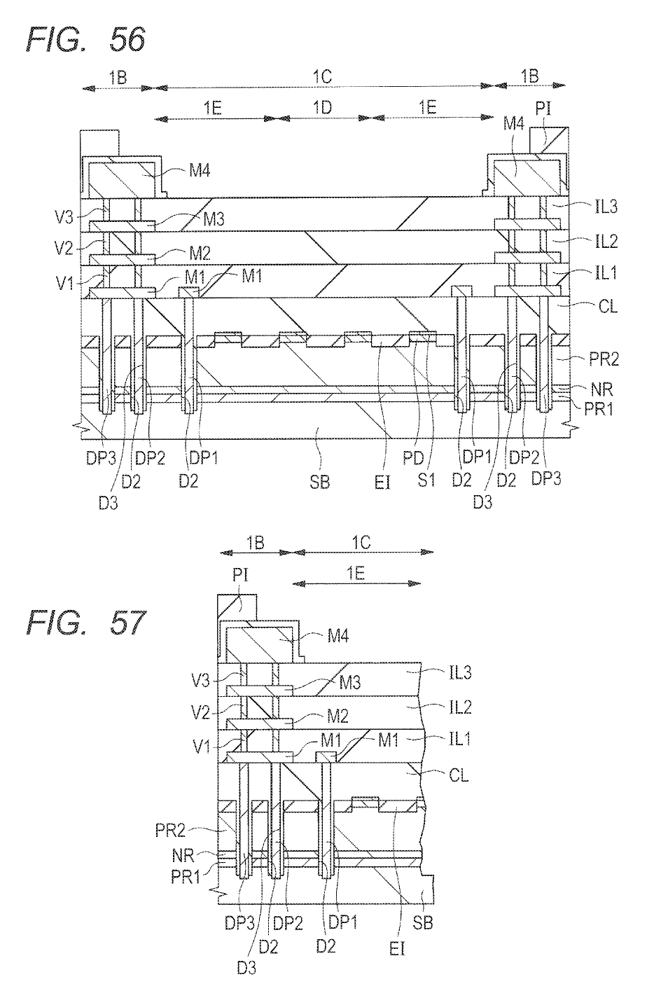

A semiconductor device of a seventh modification of the third embodiment is described with reference to FIGS. 56 and 57. FIGS. 56 and 57 are each a sectional view of the semiconductor device of the seventh modification. The semiconductor device of FIG. 56 corresponds to part of a semiconductor wafer before a dicing step. FIG. 57 shows an end portion of a semiconductor chip after the dicing step.

As shown in FIGS. 56 and 57, the fifth modification of the third embodiment may be combined with the second embodiment. Specifically, the dummy substrate contact plugs DP2 and DP3 may be provided directly below the interconnection M1 in the seal ring region 1B while the annular dummy substrate contact plug DP1 surrounding the circuit region 1A and the seal ring region 1B is formed in the peripheral region 1E.

In the seventh modification, the dummy substrate contact plugs DP1, DP2, and DP3 are thus disposed. Since the dummy substrate contact plug DP1 has a high ability of preventing advancement of the cracking and chipping compared with the DTI structure (dummy isolation part) including the gap, the seventh modification can more effectively prevent advancement of the cracking and chipping compared with the fifth modification and the sixth modification of the third embodiment and with the second embodiment.

Although the invention achieved by the inventors has been described in detail according to the embodiments hereinbefore, the invention should not be limited thereto, and it will be appreciated that various modifications or alterations thereof may be made within the scope without departing from the gist of the invention.

What is claimed is:

1. A semiconductor device, comprising:
a semiconductor substrate having a first region, a second region surrounding the first region in plan view, and a third region surrounding the first region in plan view;
a plurality of elements formed in the vicinity of an upper surface of the semiconductor substrate in the first region, and configuring a circuit;
an element isolation part buried in a first trench formed in the upper surface of the semiconductor substrate, and isolating the elements from one another;
a first interconnection formed over the semiconductor substrate in the second region with an interlayer insulating film in between, and configuring no circuit;
a first conductive coupling part coupled to the first interconnection while penetrating the interlayer insulating film in the second region, and configuring no circuit; and
a third trench formed in the upper surface of the semiconductor substrate in the third region, and having a deeper depth than the first trench,
wherein each of the first interconnection, the first conductive coupling part, and the third trench is formed annually surrounding the first region in plan view.

2. The semiconductor device according to claim 1, wherein a second trench formed in the upper surface of the semiconductor substrate in the first region, and having a deeper depth than the first trench.

3. The semiconductor device according to claim 1, wherein the third trench is formed on an outer side compared with the first conductive coupling part with respect to the first region.

4. The semiconductor device according to claim 3, wherein the third trench is formed directly below the first interconnection.

5. The semiconductor device according to claim 4, further comprising a second conductive coupling part coupled to the first interconnection while penetrating the interlayer insulating film and the third trench, and configuring no circuit.

6. The semiconductor device according to claim 5, further comprising a fourth trench formed in the upper surface of the semiconductor substrate in the fourth region surrounding the first region and the second region in plan view, and having a deeper depth than the first trench,
wherein the fourth trench is formed annually surrounding the third trench in plan view.

7. The semiconductor device according to claim 6, further comprising:
a second interconnection formed over the semiconductor substrate in the fourth region with the interlayer insulating film in between, and configuring no circuit; and
a third conductive coupling part coupled to the second interconnection while penetrating the interlayer insulating film and the fourth trench, and configuring no circuit.

8. The semiconductor device according to claim 6, wherein a gap exists in the fourth trench.

9. The semiconductor device according to claim 5, further comprising a fifth trench formed in the upper surface of the semiconductor substrate in the second region, and having a deeper depth than the first trench,
wherein the first conductive coupling part penetrates the fifth trench.

10. The semiconductor device according to claim 1, wherein a gap exists in the third trench.

11. The semiconductor device according to claim 1,
wherein the third region surrounds the second region in plan view, and
wherein the semiconductor device further comprises:
a second interconnection formed over the semiconductor substrate in the third region with the interlayer insulating film in between, and configuring no circuit; and
a third conductive coupling part coupled to the second interconnection while penetrating the interlayer insulating film and the third trench, and configuring no circuit.

12. The semiconductor device according to claim 1, wherein the third trench is exposed on a side surface of the semiconductor substrate.

13. The semiconductor device according to claim 1, wherein a crack existing in a side surface of the semiconductor substrate is terminated at a portion overlapping the third trench in plan view.

14. The semiconductor device according to claim 1,
wherein the third region surrounds the second region in plan view,
wherein the semiconductor device further comprises a sixth trench that is formed in the upper surface of the semiconductor substrate in the fifth region surrounding the first region, the second region, and the third region in plan view, and has a deeper depth than the first trench, and
wherein the sixth trench is formed annually surrounding the third trench in plan view.

15. A method of manufacturing a semiconductor device, the method comprising the steps of:
(a) providing a semiconductor substrate having a plurality of first regions, a plurality of second regions surrounding the respective first regions in plan view, and a plurality of third regions surrounding the respective first regions in plan view;
(b) forming an element isolation part buried in a first trench formed in an upper surface of the semiconductor substrate in the first region;
(c) forming a plurality of elements formed in the vicinity of the upper surface of the semiconductor substrate in the first region;
(d) after the step (c) and the step (b), forming a first interlayer insulating film over the semiconductor substrate;
(e) forming a second trench in the upper surface of the semiconductor substrate in the first region, the second trench penetrating the first interlayer insulating film and having a deeper depth than the first trench, and forming a third trench in the upper surface of the semiconductor substrate in the third region, the third trench penetrating the first interlayer insulating film, having a deeper depth than the first trench, and surrounding the first region in plan view;
(f) forming a second interlayer insulating film covering the third trench over the semiconductor substrate, thereby forming a third interlayer insulating film including the first interlayer insulating film and the second interlayer insulating film;
(g) forming a third trench penetrating the third interlayer insulating film in the first region, and forming a fourth trench penetrating the third interlayer insulating film in the second region, and surrounding the first region in plan view;
(h) forming a first conductive coupling part buried in the third trench and configuring a circuit, and forming a second conductive coupling part buried in the fourth trench and configuring no circuit; and
(i) cutting the semiconductor substrate in a fourth region between the third regions separately adjacent to each other, thereby forming a semiconductor chip including the first region, the second region, and the third region.

16. The method according to claim 15, wherein in the step (i), the fourth region is cut while having no trench deeper than the first trench in the upper surface of the semiconductor substrate.
